(19) United States
(12) Patent Application Publication
(10) Pub. No.: US 2012/0097329 A1
(43) Pub. Date: Apr. 26, 2012

(54) Stencils for High-Throughput Micron-Scale Etching of Substrates and Processes of Making and Using the Same

(75) Inventors: Eric STERN, Cambridge, MA (US); Graciela Beatriz BLANCHET, Boston, MA (US); Lindsay HUNTING, Cambridge, MA (US); Brian T. MAYERS, Arlington, MA (US); Joseph M. MCLELLAN, Quincy, MA (US); Patrick REUST, Somerville, MA (US); Ralf KÜGLER, Cambridge, MA (US); Jennifer GILLIES, Cambridge, MA (US)

(73) Assignees: Merck Patent Gesellschaft, Darmstadt (DE); Nano Terra Inc., Brighton, MA (US)

(21) Appl. No.: 13/112,166

(22) Filed: May 20, 2011

Related U.S. Application Data
(60) Provisional application No. 61/347,053, filed on May 21, 2010.

(51) Int. Cl. H01L 21/308; B29C 59/16

(52) U.S. Cl. 156/345.3; 264/447

(57) ABSTRACT

The present invention is directed to stencils for high-throughput, high-resolution etching of substrates and processes of making and using the same.

### BACKGROUND OF THE INVENTION

1. Field of the Invention

The present invention is directed to stencils suitable for high-throughput, high-resolution etching of substrates and processes of making and using the same.

2. Background

Stenciling processes, and in particular screen printing processes, are ubiquitous, and used in a multitude of industries from graphic design to electronics and photovoltaic device manufacturing. Moreover, traditional stencil processes are attractive for low-cost patterning of a wide variety of substrates, because the techniques are applicable to non-planar, roughened, and/or composite substrates. However, commercially viable high-throughput processes for stenciling patterns that have a lateral resolution less than 50 μm have yet to be developed. In large part this is because stenciling processes such as screen printing typically utilize a woven mesh that forms a backing or support layer onto which blocking regions are adhered. The woven mesh is stretched across a frame and coated with a photoresist termed an “emulsion,” which is exposed through a mask to provide a desired pattern. After exposure, the cured emulsion takes the shape (form) of the woven mesh, which is clearly visible through the cured emulsion. The highest density commercially available meshes consist of fibers that are approximately 30 μm in diameter. Furthermore, although woven meshes are pressure annealed to secure the weave, there is significant topography in the surface of the woven mesh (i.e., >30-40 μm in the vertical dimension), which allows ink that passes through the woven mesh to spread laterally at the edges of the cured emulsion due to non-conformal contact bet ween the mesh and substrate. While this edge-bleed is not a concern for patterns having lateral dimensions of several hundreds of microns, it limits the applicability of traditional stencil processes to applications in which sub-50 μm resolution is not required.

While patterns that include features of about 50 μm in size have been achieved using a stainless steel screen having a mesh count of about 350 to about 500, such processes are not feasible for patterns requiring a resolution below 50 μm or patterns on non-planar substrates. Furthermore, screen printing processes can have difficulty patterning both small- and large-dimension features using the same screen and ink composition.

### BRIEF SUMMARY OF THE INVENTION

What is needed are stencils and processes for reproducibly etching a wide variety of substrates with a lateral dimension of 50 μm or less. The stencils and processes should be low-cost, highly reproducible and scalable. In particular, the stencils and processes of the present invention can produce features having at least one lateral dimension of 50 μm or less while at the same time forming features having much larger lateral dimensions.

In order to achieve sub-50 μm, high-resolution screen printing, high resolution patterns must not only be supported on the mesh but the stencil must also make conformal contact with the substrate. In order to meet these requirements we have developed a process to create a small-microporous-to-nanoporous membrane surrounding a woven mesh. The mesh provides the structural support and the membrane is formed from an elastomeric material and binds to the mesh. The mesh is contained within the porous membrane, such that both surfaces of the resulting hybrid structure are micro-nanoporous.

The present invention is directed to an article of manufacture comprising a first layer comprising a flexible mesh; and a second layer affixed to the first layer, the second layer comprising a plurality of nanowires, the nanowires having a diameter of 80 nm to 10 μm.

The present invention is also directed to a stencil comprising a first layer comprising a flexible mesh, and a second layer affixed to the first layer, the second layer comprising a plurality of nanowires, the nanowires having a diameter of 80 nm to 10 μm, wherein a pattern having at least one lateral dimension of 500 μm or less is present in or on the second layer, and wherein the flexible porous backing has a permeability suitable for flowing an etch paste there through and the pattern is impermeable to the etch paste.

In some embodiments, the nanowires comprise a polymer selected from: polyethylene, polypropylene, polyethylene terephthalate, polyvinylpyrrolidone, and combinations thereof.

In some embodiments, the nanowires have an average diameter of 200 nm to 6 μm, or 200 nm to 800 nm. In some embodiments, the second layer of the stencil has a thickness of 500 nm to 20 μm.

In some embodiments, the pattern comprises an opaque material selected from the group consisting of: a polymer, an elastomer, a metal, and combinations thereof.

The present invention is directed to a stencil comprising a contact surface that includes: a photoimaged elastomeric composition having at least one opening there through that includes at least one opening there through that defines a pattern in the stencil having at least one lateral dimension of 50 μm or less, wherein the photoimaged elastomeric composition is suitable for conformally contacting a substrate, and a stability layer affixed to a backside of the photoimaged elastomeric composition, wherein the stability layer has substantially the same lateral dimensions as the photoimaged elastomeric composition, and wherein the stability layer has a Shore Type D hardness of 50 or more; and a flexible porous backing affixed to the stability layer, wherein the flexible porous backing has a permeability suitable for flowing an etch paste there through.

The present invention is also directed to a process for preparing a stencil, the process comprising:

disposing a lift-off layer onto a master that includes at least one light-blocking region that forms an optically transparent pattern;

disposing a photoimageable elastomeric formulation onto the lift-off layer;

illuminating and developing the photoimageable elastomeric formulation to form a contact layer comprising a photoimaged elastomeric composition having at least one opening there through that defines a pattern in the stencil having at least one lateral dimension of 50 μm or less;

disposing a photoimageable formulation onto the contact layer;

contacting a flexible porous backing with at least a portion of the photoimageable formulation;

illuminating the photoimageable formulation to form a stability layer affixed to both the contact layer and the flexible porous backing, wherein the stability layer has a Shore Type D harness of 50 or more, and has lateral dimensions substantially the same as the contact layer; and

removing the stencil from the master by separating or removing the lift-off layer from the stencil.

In some embodiments, the photoimageable elastomeric formulation does not substantially phase separate prior to the illuminating and developing, and the photoimageable formulation does not substantially phase separate prior to the illuminating.

In some embodiments, the process comprises prior to the disposing the photoimageable formulation onto the contact layer, oxygen plasma-treating the contact layer and depositing an adhesion promoter onto the oxygen plasma-treated contact layer.

In some embodiments, the process comprises prior to the contacting the flexible porous backing with at least a portion of the photoimageable formulation, oxygen plasma-treating a surface of the flexible porous backing and depositing an adhesion promoter onto the oxygen plasma-treated flexible porous backing. Adhesion promoters suitable for use with the present invention include, but are not limited to, trichloro(vinyl)silane, trimethoxy(vinyl)silane, triethoxy(vinyl)silane, 2-acryloxyethoxytrimethoxy silane, 2-acryloxyethoxytriethoxy silane, 2-acryloxyethoxytrichlorosilane, N-3-acryloxy-2-hydroxypropyl-3-aminopropyltriethoxysilane, acryloxymethyltrimethoxysilane, acryloxymethyltriethoxysilane, acryloxymethyltrichlorosilane, acryloxymethyl phenethyltrimethoxysilane, 3-N-allylaminopropyltrimethoxysilane, allyltrimethoxysilane, allyltriethoxysilane, allyltrichlorosilane, and combinations thereof.

The present invention is also directed to a process of etching a substrate, the process comprising:

conformally contacting the contact surface of a stencil of the present invention with a substrate;

flowing an etch paste comprising an etchant through the porous backing assembly and the at least one opening in the stencil to provide a pattern of etch paste on the substrate;

reacting the etch paste with the substrate, wherein the reacting removes a portion of the substrate to provide a pattern on the substrate having at least one lateral dimension of 50 μm or less; and

removing the stencil from the substrate.

The present invention is also directed to a process of etching a substrate, the process comprising:

conformally contacting the contact surface of a stencil of the present invention with a substrate;

flowing an etch paste comprising an etchant through the porous backing assembly and the at least one opening in the stencil to provide a pattern of etch paste on the substrate;

removing the stencil from the substrate; and

reacting the pattern of etch paste with the substrate, wherein the reacting removes a portion of the substrate to provide a pattern on the substrate having at least one lateral dimension of 50 μm or less.

In some embodiments, the reacting comprises applying thermal energy to the etch paste, the substrate, or a combination thereof. In some embodiments, an etch paste for use with the present invention has a viscosity of 100 cP or more.

In some embodiments, pressure is not applied to the stencil or the substrate during the conformally contacting. In some embodiments, a process of the present invention comprises cleaning the patterned substrate. In some embodiments, a process of the present invention comprises, prior to the conformally contacting, pre-treating the contact surface of the stencil, the substrate, or both, with an oxygen plasma.

In some embodiments, a process comprises after the flowing, increasing the viscosity of an etch paste.

In some embodiments, the at least one opening of the stencil has at least one lateral dimension of 1 μm to 10 μm.

In some embodiments, the photoimaged elastomeric composition has a thickness of 1 μm to 10 μm. In some embodiments, the photoimaged elastomeric composition has a Shore Type A hardness of 5 to 95. In some embodiments, the photoimaged elastomeric composition comprises an elastomer, a cross-linker, a photoinitiator, a free radical scavenger, and an optional oxygen scavenger.

In some embodiments, the photoimaged elastomeric composition comprises a cross-linker in a concentration of 0.5% to 65% by weight, a photoinitiator in a concentration of 0.01% to 10% by weight, a free radical scavenger in a concentration of 0.01% to 15% by weight, and an optional oxygen scavenger in a concentration of 0.01% to 10% by weight.

Elastomers suitable for use in the photoimaged elastomeric composition include a styrene-butadiene-styrene block copolymer, a styrene-isoprene-styrene block copolymer, a copolymer of acrylonitrile and butadiene, a neoprene rubber, and combinations thereof. In some embodiments, the elastomer is a styrene-butadiene-styrene block copolymer that is present in a concentration of 30% to 99% by weight.

In some embodiments, the stability layer has a thickness of 5 μm to 50 μm.

In some embodiments, the stability layer comprises a photoimaged polymer composition that includes an aliphatic urethane diacrylate polymer, an optional cross-linker, a photoinitiator, a free radical scavenger, and an optional oxygen scavenger.

In some embodiments, the photoimaged polymer composition comprises an aliphatic urethane diacrylate polymer in a concentration of 5% to 99% by weight, an optional cross-linker in a concentration of 0.5% to 90% by weight, a photoinitiator in a concentration of 0.01% to 10% by weight, a free radical scavenger in a concentration of 0.01% to 15% by weight, and an optional oxygen scavenger in a concentration of 0.01% to 10% by weight.

In some embodiments, the flexible porous backing comprises a flexible mesh. In some embodiments, a flexible mesh for use with the present invention has openings with a lateral dimension of 1 μm to 100 μm.

In some embodiments, the flexible porous backing comprises a porous membrane affixed to the stability layer, wherein the porous membrane has an average pore size of 5 μm or less; and a flexible mesh affixed to the porous membrane, wherein the flexible mesh has openings with a lateral dimension greater than the pore size of the porous membrane.

In some embodiments, the porous membrane has an average pore size of 15 μm or less. In some embodiments, the porous membrane has a thickness of 500 nm to 20 μm.

In some embodiments, a thin layer comprising a heat-treated polyolefin is present between the porous membrane and the flexible mesh. Polyolefins suitable for use with the present invention include, but are not limited to, polyethylene, polypropylene, and combinations thereof.

Thus, the present invention is also directed to a process for preparing a flexible backing layer, the process comprising: annealing an assembly that includes a porous membrane having an average pore size of 15 μm or less, a flexible mesh, and a plurality of polyolefin-containing particles there between, for a time, and at a temperature and pressure sufficient to affix the porous membrane to the flexible mesh to provide a flexible porous backing for the stencil.

In some embodiments, the polyolefin-containing particles comprise a polymer selected from: polyethylene, polypropylene, and combinations thereof.

In some embodiments, the flexible porous backing comprises a layer of nanowires affixed to the stability layer, wherein the nanowires have an average diameter of 80 nm to 10 μm; and a flexible mesh affixed to the layer of nanowires. In some embodiments, the nanowires have an average diameter of 200 nm to 2 μm. In some embodiments, a layer of nanowires has a thickness of 500 nm to 20 μm.

Thus, the present invention is also directed to a process for preparing a flexible backing layer, the process comprising providing an assembly that includes a layer of nanowires affixed to a flexible mesh, wherein the nanowires have an average diameter of 80 nm to 10 μm.

In some embodiments, a lift-off layer comprises a water soluble polymer. Water soluble polymers suitable for use with the present invention include, but are not limited to, a polyvinyl alcohol, a hydroxyalkyl cellulose, a polysaccharide, a polyvinyl pyrrolidone, and combinations thereof.

Further embodiments, features, and advantages of the present inventions, as well as the structure and operation of the various embodiments of the present invention, are described in detail below with reference to the accompanying drawings.

### BRIEF DESCRIPTION OF THE DRAWINGS

The accompanying drawings, which are incorporated herein and form a part of the specification, illustrate one or more embodiments of the present invention and, together with the description, further serve to explain the principles of the invention and to enable a person skilled in the pertinent art to make and use the invention.

FIG. 1 provides a three-dimensional cross-sectional representation of a stencil of the present invention.

FIGS. 2A-2B provide cross-sectional representations of stencils of the present invention.

FIGS. 3A-3I provide a cross-sectional schematic diagram of a process suitable for preparing a stencil of the present invention.

FIGS. 4A-4C provide a cross-sectional schematic diagram of a process suitable for preparing a composite backing for use with a stencil of the present invention.

FIG. 5 provides a SEM image of a patterned elastomeric photoresist on a porous backing layer.

FIG. 6 provides a photographic image of a stencil of the present invention.

FIG. 7 provides a SEM image of a stencil comprising a woven polymer mesh having a patterned elastomer layer applied thereon.

One or more embodiments of the present invention will now be described with reference to the accompanying drawings. In the drawings, like reference numbers can indicate identical or functionally similar elements. Additionally, the left-most digit(s) of a reference number can identify the drawing in which the reference number first appears.

### DETAILED DESCRIPTION OF THE INVENTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “some embodiments,” “one embodiment,” “an embodiment,” “an example embodiment,” etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

References to spatial descriptions (e.g., “above,” “below,” “up,” “down,” “top,” “bottom,” etc.) made herein are for purposes of description and illustration only, and should be interpreted as non-limiting upon the stencils, substrates, processes and products of any process of the present invention, which can be spatially arranged in any orientation or manner.

Throughout the specification, use of the term “about” with respect to any quantity is contemplated to include that quantity. For example, “about 10 μm” is contemplated herein to include “10 μm,” as well as values understood in the art to be approximately 10 μm with respect to the entity described.

### Stencils

The present invention is directed to a stencil capable of reproducibly etching a substrate with a pattern that includes a lateral dimension of 50 μm or less. The stencils comprise a contact surface supported on a flexible porous backing in a manner such that the contact surface can conformally contact a substrate without distortion of the pattern dimensions and without applying pressure to the backside of the stencil and/or a substrate. The contact surface includes a photoimaged elastomeric composition having at least one opening there through that defines a pattern in the stencil having at least one lateral dimension of 50 μm or less, wherein the photoimaged elastomeric composition is suitable for conformally contacting a substrate. Conformal contact between the photoimaged elastomeric composition and the substrate prevents regions of the substrate that are in contact with the stencil from reacting with an etch paste applied through the porous backing layer of the stencil. The stencils also comprise a stability layer affixed to a backside of the photoimaged elastomeric composition, wherein the stability layer has substantially the same lateral dimensions as the photoimaged elastomeric composition. The stability layer has a Shore Type D hardness of 50 or more. The stability layer is located between the contact layer and the porous backing and stabilizes the contact layer, in particular by preventing random or systematic variations in the surface roughness, waviness, and/or topography of the porous backing layer from preventing conformal contact between the contact layer and a substrate. The flexible porous backing is affixed to the stability layer, and has a permeability suitable for flowing an etch paste there through. The flexible porous backing layer also is prepared from a materials suitable for maintaining the dimensional stability of the contact layer in the x-y plane, while being capable of bending, rolling, and/or distorting in the z-direction (i.e., away from a substrate).

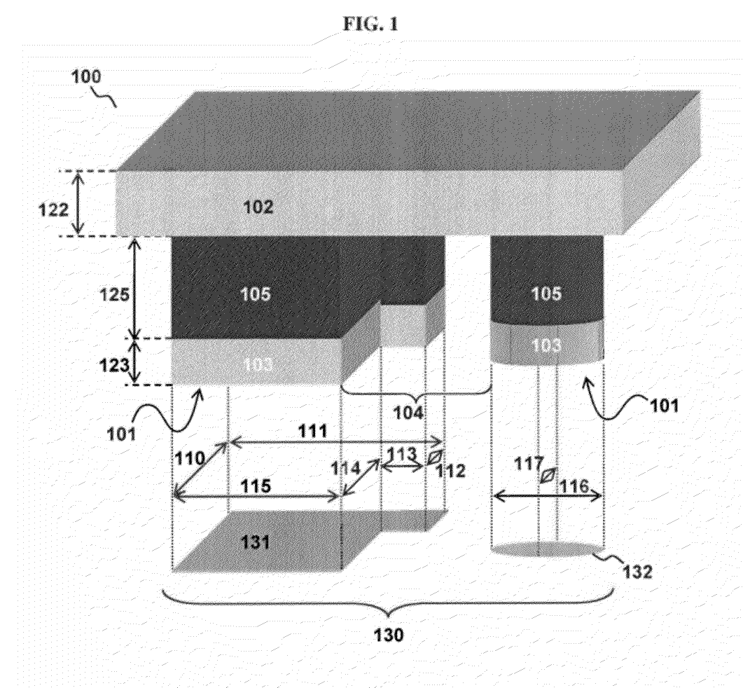

FIG. 1 provides a three-dimensional representation of a stencil of the present invention, 100. Referring to FIG. 1, the stencil, 100, includes a contact surface, 101, that comprises a photoimaged elastomeric composition, 103. The contact surface, 101, is suitable for conformally contacting a substrate. As used herein, “suitable tor conformally contacting a substrate” means that when a stencil is placed in contact with a substrate, the contact surface of the stencil does not laterally distort and conformally contacts a substrate without applying pressure to a backside of the stencil and/or the substrate.

The contact surface comprises a photoimaged elastomeric composition and is therefore capable of elastically deforming. However, it is not necessary for the photoimaged elastomeric composition to elastically deform in order to conformally contact a substrate. This is because deformation of the photoimaged elastomeric composition can change the lateral dimensions, as illustrated at 110-117 of FIG. 1, of at least one opening in the stencil, and can lead to irregular etching, as well as degradation of the contact surface and stencil.

In some embodiments, conformal contact is enabled by controlling the Shore hardness and/or the surface energy of the of the photoimaged elastomeric composition. In some embodiments, a photoimaged elastomeric composition has a Shore Type A hardness of 5 to 95, 5 to 75, 5 to 50, 5 to 25, 10 to 95, 10 to 75, 10 to 50, 10 to 25, 20 to 95, 20 to 75, 20 to 50, 30 to 95, 30 to 75, 40 to 95, 40 to 75, 50 to 95, 50 to 75, 60 to 95, 70 to 95, or 80 to 95.

In some embodiments, conformal contact between a contact surface and a substrate is enabled by controlling the surface energy of the contact surface. For example, minimization of the surface energy of the contact surface can enhance conformal contact with a substrate. In some embodiments, a hydrophilic paste or ink is used, wherein the hydrophilic paste or ink has a water contact angle on the back surface of a flexible porous backing of 50° to 160°, 60° to 150°, or 70° to 145°. In some embodiments, a hydrophobic paste or ink is used, wherein the hydrophobic paste or ink has a water contact angle on the back surface of a flexible porous backing of 0° to 120°, 10° to 100°, or 15° to 75°.

Referring FIG. 1, the contact surface, 101, has at least one opening there through, 104, and the stability layer, 105, has substantially the same lateral dimensions as the photoimaged elastomeric composition, 110-117. The at least one opening in a stencil defines a pattern, 130, in the stencil having lateral dimensions, 110-117, wherein at least one lateral dimension is 50 μm or less. As used herein, “having lateral dimensions, wherein at least one lateral dimension is 50 μm or less,” is used interchangeably with “at least one lateral dimension of 50 μm or less,” and both refer to a pattern in a stencil defined by at least one opening, wherein the pattern includes one or more lateral dimensions of 50 μm or less. Thus, it is not necessary for every lateral dimension, 110-117, of a pattern in a stencil, 130, to be 50 μm or less, and a pattern in a stencil can include one or more lateral dimensions greater than 50 μm. Nor is it a requirement for every element of a pattern in a stencil to include a lateral dimension of 50 μm or less. For example, stencil pattern 130 includes elements 131 and 132, wherein when the lateral dimensions 110-115 of element 131 include at least one lateral dimension of 50 μm or less, then pattern element 132 having lateral dimensions 116-117 can: a) also include at least one lateral dimension (116-177) of 50 μm or less; b) include only lateral dimensions greater than 50 μm; or c) include only lateral dimensions less then 50 μm.

In some embodiments, a pattern in a stencil has at least one lateral dimension of 40 μm or less, 30 μm or less, 20 μm or less, 10 μm or less, 5 μm or less, 2 μm or less, or 1 μm or less. In some embodiments, the at least one opening of the stencil has at least one lateral dimension of 0.5 μm to 50 μm, 0.5 μm to 25 μm, 0.5 μm to 25 μm, 0.5 μm to 10 μm to 50 μM, 1 μm to 25 μm, 1 μm to 10 μm, 2 μm to 50 μm, 2 μm to 25 μm, 2 μm to 10 μm, 5 μm to 50 μm, 5 μm to 25 μm, 10 μm to 50 μm, 10 μm to 25 μm, or μm to 50 μm.

In some embodiments, a stencil comprises a contact layer having a surface area of about 40,000 mm² or greater, about 50,000 mm² or greater, about 60,000 mm² or greater, about 75,000 mm² or greater, about 100,000 mm² or greater, about 125,000 mm² or greater, or about 150,000 mm² or greater.

Referring to FIG. 1, the photoimaged elastomeric composition, 103, has a thickness, 123, of 1 μm to 10 μm, 1 μm, 1 μm to 7.5 μm, 1 μm to 5 μm, 1 μm to 2.5 μm, 2.5 μm to 10 μm, 2.5 μm to 7.5 μm, 2.5 μm to 5 μm, 5 μm to 10 μm, or 7.5 μm to 10 μm. The stability layer, 105, has a thickness, 125, of 5 μm to 50 μm, 5 μm to 40 μm, 5 μm to 30 μm, 5 μm to 20 μm, 10 μm to 50 μm, 10 μm to 40 μm, 10 μm to 30 μm, or 20 μm to 50 μm. In some embodiments, the photoimaged elastomeric composition, 103, and the stability layer, 105, are present such that a ratio of the thickness of the photoimaged elastomeric composition, 123, to the thickness of the stability layer, 125, is 1:2 to 1:10, 1:3 to 1:8, 1:2, 1:3, 1:4, 1:5, 1:6, 1:8, or 1:10.

Not being bound by any particular theory, as the thickness of a photoimaged elastomeric composition increases, the Shore Type A hardness of the photoimaged elastomeric composition also increases. For example, in some embodiments a photoimaged elastomeric composition has a thickness of 1 μm and a Shore Type A hardness of 5 to 25; a thickness of 2.5 μm and a Shore Type A hardness of 10 to 50; a thickness of 5 μm and a Shore Type A hardness of 30 to 75; a thickness of 7.5 μm and a Shore Type A hardness of 40 to 95; or a thickness of 10 μm and a Shore Type A hardness of 60 to 95.

Stencils suitable for etching substrates with a lateral dimension of 50 μm or less require high resolution patterns that are supported on a porous backing, and also capable of conformally contacting a substrate. The present invention utilizes a contact layer comprising an elastomeric composition to conformally contact a substrate. The elastomeric properties of the photoimaged elastomeric composition enable conformal contact to be achieved across both planar, curved, and/or roughened substrate.

Referring to FIG. 1, the working surface, 101, of the stencils is formed by the contact layer, 103, which is adhered to a porous backing, 102, and protects an area of the substrate during patterning. In order for the contact layer, 103, to conformally contact a substrate across the entire surface area of a stencil, it is imperative that any surface roughness or variations in the topography of a porous backing do not affect the contact layer. Thus, the stencils of the present invention prevent the topography of a porous backing from adversely affecting the contact layer by utilizing a stability layer. As discussed above, the stability layer, 105, is affixed to a backside of the contact layer, 103, and also adhered to a porous backing, 102, thereby preventing deviations in the surface topography of the porous backing from adversely affecting conformal contact of the contact layer with a substrate. The stability layer has a thickness, 125.

Not being bound by any particular theory, the thickness of the stability layer depends upon the variations in the topography of the porous backing. Specifically, a stencil comprising a porous backing having a high degree of variation in the topography requires a thicker stability layer to ensure that the contact is capable of conformally contacting a substrate.

In some embodiments, a stability layer has a thickness of 5 μm to 50 μm, 5 μm to 40 μm, 5 μm to 30 μm, 5 μm to 25 μm, 5 μm to 20 μm, 5 μm to 10 μm, 10 μm to 50 μm, 10 μm to 25 μm, 20 μm to 50 μm, 25 μm to 50 μm, or 30 μm to 50 μm.

In order to fabricate the stencils in a high-throughput, high-resolution and highly-reproducible manner, both the contact surface and the stability layer are prepared from photoimageable formulations. The photoimageable elastomeric formulation (used as a precursor for the photoimaged elastomeric composition) comprises an elastomer, a cross-linker, a photoinitiator, a free radical scavenger, and an optional oxygen scavenger. The photoimageable polymer formulation (used as a precursor for the stability layer) comprises a photoimageable polymer, an optional cross-linker, a photoinitiator, a free radical scavenger, and an optional oxygen scavenger.

Elastomers suitable for use in a photoimaged elastomeric composition are reactive with a UV-absorbing photoinitiator. Elastomers suitable for use with the present invention include, but are not limited to, a polyurethane, a resilin, an elastin, a polyimide, a phenol formaldehyde polymer, a polydialkylsiloxane (e.g., polydimethylsiloxane, “PDMS” such as SYLGARD® products available from Dow Corning, Midland, Mich.), a natural rubber, a polyisoprene, a butyl rubber, a halogenated butyl rubber, a polybutadiene, a styrene butadiene, a nitrile rubber, a hydrated nitrile rubber, a chloroprene rubber (e.g., polychloroprene, available as NEOPRENE™ and BAYPREN®, Farbenfabriken Bayer AG Corp., Leverkusen-Bayerwerk, Germany), an ethylene propylene rubber, an epichlorohydrin rubber, a polyacrylic rubber, a silicone rubber, a fluorosilicone rubber, a fluoroelastomer (for example, those described herein, supra), a perfluoroelastomer, a tetrafluoroethylene/propylene rubber, a chlorosulfonated polyethylene, an ethylene vinyl acetate, cross-linked variants thereof, halogenated variants thereof, and combinations thereof. Other suitable materials and processes to prepare elastomeric stamps suitable for use with the present invention are disclosed in U.S. Pat. Nos. 5,512,131; 5,900,160; 6,180,239; and 6,776,094; and pending U.S. Pub. No. 2004/0225954, all of which are incorporated herein by reference in their entirety. Additional stamps suitable for use with the present invention and processes of preparing the stamps are provided in co-pending U.S. Pub. Nos. 2008/0230773, 2009/0041984 and U.S. Appl. No. 61/165,755, all of which are incorporated herein by reference in their entirety.

In some embodiments, an elastomer is present in a photoimaged elastomeric composition in a concentration of 0.5% to 75%, 0.5% to 65%, 0.5% to 50%, 0.5% to 35%, 0.5% to 25%, 0.5% to 20%, 0.5% to 15%, or 0.5% to 10% by weight of the photoimaged elastomeric composition.

In some embodiments, a photoimaged elastomeric composition comprises an elastomer selected from: a styrene-butadiene-styrene block copolymer, a styrene-isoprene-styrene block copolymer (e.g., HYBRAR® 5125 available from Kuraray Co., Ltd., Tokyo, Japan), a copolymer of acrylonitrile and butadiene, a neoprene rubber, and combinations thereof. In some embodiments, the elastomer is a styrene-butadiene-styrene block copolymer that is present in a concentration of 30% to 99% by weight of the photoimaged elastomeric composition.

In some embodiments, an elastomer for use with the present invention has a Young's modulus of 20 MPa or less, 15 MPa or less, 10 MPa or less, 7.5 MPa or less, 5 MPa or less, or 2 MPa or less. In some embodiments, an elastomer for use with the present invention has a Young's modulus of 2 MPa to 20 MPa, 2 MPa to 15 MPa, 2 MPa to 10 MPa, 5 MPa to 20 MPa, 5 MPa to 15 MPa, or 10 MPa to 20 MPa.

The photoimageable elastomeric formulation comprises a cross-linker having a lower molecular weight than the elastomer and two or more functional groups suitable for reacting with the elastomer. Functional groups include, but are not limited to, vinyl, allyl, acryl, acrylate, carboxyl, and the like, and combinations thereof. After reaction, the cross-linker forms a cross-linked network with an elastomer to provide a photoimaged elastomeric composition.

Cross-linkers for use with the present invention include, but are not limited to, polyacrylates selected from: propoxylated neopentyl glycol diacrylate (available as, e.g., SR-9003 from Sartomer, Exton, Pa.), ethylene diacrylate (CAS No. 2274-11-5), diethylene glycol diacrylate, polyethylene glycol diacrylate (CAS No. 26570-48-9), tripropylene glycol diacrylate, butadiene diacrylate, hexamethylene diacrylate (CAS No. 13048-33-4), 1,6-hexane diol diacrylate, a bisphenol A diacrylate (available from, e.g., Sartomer as SR-306, SR-349, SR-601, SR-602, and the like), 1,12 dodecanediol dimethacrylate (available as, e.g., SARTOMER® CD262, Sartomer USA, LLC, Exton, Pa.), trimethylolpropane triacrylate, trimethyolpropane ethoxytriacrylate, and combinations thereof.

In some embodiments, a cross-linker is present in a photoimaged elastomeric composition in a concentration of 0.5% to 75%, 0.5% to 65%, 0.5% to 50%, 0.5% to 35%, 0.5% to 25%, 0.5% to 20%, 0.5% to 15%, or 0.5% to 10% by weight. The same cross-linkers described herein can be optionally present in the photoimageable polymer formulation (stability layer) in the same percentages by weight.

In order to form a uniform photoimaged elastomeric composition suitable for conformally contacting a substrate, it is critical that the elastomer and cross-linker do not phase separate. In some embodiments, the concentration of the cross-linker is determined relative to the concentration of the elastomer. For example, the cross-linker and the elastomer can be present in a ratio of 1:1 to 1:100, 1:1 to 1:50, 1:1 to 1:10, 1:1 to 1:5, 1:2 to 1:80, 1:2 to 1:50, 1:2 to 1:10, 1:2 to 1:5, 1:2.5 to 1:50, 1:2.5 to 1:20, 1:2.5 to 1:10, 1:2.5 to 1:5, 1:3 to 1:50, 1:3 to 1:20, 1:3 to 1:10, or 1:3 to 1:5.

The photoimageable elastomeric formulations and photoimageable polymer formulations comprise a photoinitiator having an absorbance between 200 nm and 400 nm. Photoinitiators suitable for use in the photoimageable elastomeric formulation and/or the photoimageable polymer formulation include, but are not limited to, α-aminoketones (e.g., DAROCUR® 1173 from Ciba Specialty Chemicals, Tarytown, N.Y.), α-aminoketones (e.g., IRGACURE® 379 from Ciba Specialty Chemicals, Tarytown, N.Y.), benzophenone derivates (e.g., Esacure TZT available from Lamberti S.p.A.), 2,2-dimethoxy-1,2-diphenylethan-1-one (available as, e.g., IRGACURE® 651 from Ciba Specialty Chemicals, Tarytown, N.Y.), bis(2,4,6-trimethylbenzoyl)-phenylphosphineoxide (available as, e.g., IRGACURE® 819 from Ciba Specialty Chemicals, Tarytown, N.Y.), 4-(2-hydroxyethoxy)phenyl-(2-hydroxy-2-propyl)ketone (available as, e.g., IRGACURE® 2959 from Ciba Specialty Chemicals, Tarytown, N.Y.), di-(4-tert-butylcyclohexyl)-peroxydicarbonate (available as, e.g., PERKADOX® 16, Akzo Nobel N.V., Amsterdam, NL), 2-methyl-1-[4-(methylthio)phenyl]-2-morpholinopropan-1-one (available as, e.g., IRGACURE® 907 from Ciba Specialty Chemicals, Tarytown, N.Y.), and the like, and combinations thereof.

In some embodiments, a photoinitiator is present in the photoimageable elastomeric formulation and/or the photoimageable polymer formulation in a concentration of 0.01% to 20%, 0.01% to 10%, 0.01% to 5%, 0.01% to 1%, 0.05% to 15%, 0.05% to 10%, 0.1% to 10%, 0.5% to 10%, or 1% to 10% by weight of the formulation.

In some embodiments, a combination of photoinitiators is present in a photoimageable elastomeric formulation and/or a photoimageable formulation of the present invention. Not being bound by any particular theory, a combination of two or more photoinitiators can provide a wider spectral coverage and/or a difference in diffusion rates of photoactivated species during the reaction. The concentration of a first and second photoinitiator can be selected independently of one another. In some embodiments a photoimageable elastomeric formulation and/or a photoimageable formulation of the present invention comprises a first photoinitiator in a concentration of 0.01% to 20%, 0.01% to 10%, or 0.01% to 5% by weight, and a second photoinitiator in a concentration of 0.01% to 20%, 0.01% to 10%, or 0.01% to 5% by weight.

Both thin-film and/or bulk photoinitiators can be used with the formulations. In some embodiments, a thin film photoinitiator is present in a concentration of 0.01% to 10% by weight of the formulation, and a bulk photoinitiator is present in a concentration of 0.01% to 10% by weight of the formulation.

Free radical scavengers suitable for use in the photoimageable elastomeric formulation and/or the photoimageable polymer formulation include, but are not limited to, polyphenols, benzophenones, α-hydroxyketones (available as, e.g., ESACURE® DPL from Lamberti SpA), hydroquinones (e.g., monomethylhydroquinone, tert-butylhydroquinone, and the like), lauryl-N,N-diethylaminophenylsulfonylpentadienoate, and the like, and combinations thereof. In some embodiments, a free radical scavenger is present in the photoimageable elastomeric formulation and/or the photoimageable polymer formulation in a concentration of 0.01% to 15%, 0.01% to 10%, 0.01% to 5%, 0.01% to 2.5%, or 0.01% to 1% 0.1% to 15%, 0.5% to 15%, 1% to 15%, 2% to 15%, or 5% to 15% by weight of the formulation.

Oxygen scavengers suitable for use in the photoimageable elastomeric formulation and/or the photoimageable polymer formulation include, but are not limited to, phenols and derivatives thereof, and the like. In some embodiments, an oxygen scavenger is present in the photoimageable elastomeric formulation and/or the photoimageable polymer formulation in a concentration of 0.01% to 10%, 0.01% to 5%, 0.01% to 2.5%, 0.01% to 1%, 0.05% to 5%, or 0.1% to 2% by weight of the formulation.

In some embodiments, a photoimaged elastomeric composition comprises an elastomer in a concentration of 30% to 99% by weight, a cross-linker in a concentration of 0.5% to 65% by weight, a photoinitiator in a concentration of 0.01% to 20% by weight, a free radical scavenger in a concentration of 0.01% to 15% by weight, and an optional oxygen scavenger in a concentration of 0.01% to 10% by weight.

In some embodiments, the photoimaged elastomeric composition comprises a styrene-butadiene-styrene block copolymer in a concentration of 15% to 30% by weight, propoxylated neopentyl glycol diacrylate in a concentration of 1% to 20% by volume, a photoinitiator in a concentration of 0.01% to 20% by weight, a second photoinitiator in a concentration of 0.01% to 5% by weight, and lauryl-N,N-diethylaminophenylsulfonylpentadienoate (a free radical scavenger) in a concentration of 0.01% to 5% by weight.

As discussed above, the photoimageable polymer formulation (used as a precursor for the stability layer) comprises a photoimageable polymer, an optional cross-linker, a photoinitiator, a free radical scavenger, and an optional oxygen scavenger. Photoimageable polymers suitable for use with the stability layer include polymers having one or more photoreactive groups such as, but are not limited to, a polyurethane polymer comprising acrylic groups (e.g., an aliphatic urethane diacrylate such as EBECRYL® 280/15IB available from Cytec Industries, Inc., Wilmington, Del.), a vinyl-terminated monomer (e.g., 1,3,5-triallyl-1,3,5-triazine-2,4,6(1H,3H,5H)-trione), a mercapan-terminated monomer (e.g., pentaerythritol tetrakis(2-mercaptoacetate)), and the like, and combinations thereof. The photoimageable polymer is present in a concentration of 1% to 99%, 2% to 98%, 5% to 95%, 10% to 95%, 25% to 95%, 50% to 95%, 75% to 95%, or 25% to 75%, by weight of the formulation.

In some embodiments, the photoimageable polymer formulation comprises an aliphatic urethane diacrylate polymer in a concentration of 5% to 99% by weight, an optional cross-linker in a concentration of 0.5% to 90% by weight, a photoinitiator in a concentration of 0.01% to 10% by weight, a free radical scavenger in a concentration of 0.01% to 15% by weight, and an optional oxygen scavenger in a concentration of 0.01% to 10% by weight.

The photoimageable elastomeric formulation and photoimageable polymer formulation can be in the form of a solution, suspension, gel, semi-solid, or solid. In some embodiments, the formulations comprise a solvent. In some embodiments, a solvent has a vapor pressure of 30 mm Hg or less at 25° C. Suitable solvents for use with the present invention include, but are not limited to, optionally substituted alkyl solvents (e.g., hexanes), aromatic solvents (e.g., xylene, toluene, and the like), amides (e.g., NMP, DMF, DMA, and the like), and combinations thereof.

The photoimageable elastomeric formulation and/or the photoimageable polymer formulation can be optionally suspended, dissolved, or otherwise combined with a solvent in a concentration of 0.001 wt-% to 100 wt-% (i.e., 0.001-100 g per 100 mL solvent). The following compositions are described in terms of the solids content of the formulations and compositions. A formulation provided as a solution or suspension can be spin- or draw-coated onto a substrate. After coating a substrate with a formulation, a coating is exposed to UV light and the photoimaged coating is developed with a suitable developer such as toluene.

Not being bound by any particular theory, the photoimageable polymer formulation and the photoimageable elastomeric composition strongly adhere to glass, plastic, metal, or other materials functionalized with vinyl, acrylic, or other UV-reactive functional groups.

Referring to FIG. 1, the porous backing, 102, comprises a material suitable for adhering to the stability layer, 105, and having a permeability suitable for flowing an etch paste there through. The porous backing, 102, has a thickness, 122. In some embodiments, the porous backing has a thickness of 1 μm to 1 mm, 1 μm to 500 μm, 1 μm to 250 μm, 1 μm to 100 μm, 1 μm to 50 μm, 1 μM to 25 μm, 1 μm to 10 μm, 1 μm to 5 μm, 2 μm to 1 mm, 2 μm to 500 μm, 2 μm to 100 μM, 2 μm to 50 μm, 2 μm to 25 μm, 2 μm to 10 μm, 5 μm to 1 mm, 5 μm to 500 μm, 5 μm to 100 μm, 5 μm to 50 μm, 5 μm to 25 μM, 10 μm to 500 μm, 10 μm to 50 μm, about 1 μm, about 2.5 μm, about 5 μm, about 10 μm, or about 20 μm.

In some embodiments, the porous backing comprises a flexible mesh of woven fibers having a diameter of about 50 μm or less, about 30 μm or less, or about 20 μm or less.

In some embodiments, the porous backing comprises a flexible mesh having openings of 1 μm to 100 μm, 1 μm to 75 μm, 1 μm to 50 μm, 1 μm to 25 μm, 1 μm to 10 μm, 5 μm to 100 μm, 5 μm to 50 μm, 10 μm to 100 μm, 10 μm to 50 μm, 20 μm to 100 μm, 20 μm to 75 μm, or 50 μm to 100 μm.

Flexible meshes suitable for use with the present invention include, but are not limited to, polymers (e.g., polyethylene, high-density polyethylene, polypropylene, polyethylene terephthalate, polyvinylchloride, polystyrene, nylon, polycarbonate, polylactic acid, and the like), fiberglass, stainless steel, and combinations thereof.

In some embodiments, a porous membrane having an average pore size of 5 μp or less is affixed to a flexible mesh, wherein the flexible mesh has openings with a lateral dimension greater than the pore size of the porous membrane. In such embodiments the porous membrane is in contact with the stability layer and a front surface of the flexible mesh. In some embodiments, a porous membrane has an average pore size of 15 μm or less, 10 μm or less, 7.5 μm or less, or 5 μm or less. In some embodiments, a porous membrane for use in a porous backing of the present invention has an average pore size of 1 μm to 15 μm, 1 μm to 10 μm, 1 μm to 7.5 μm, 1 μm to 5 μm, 2.5 μm to 15 μm, 2.5 μm to 10 μm, 2.5 μm to 7.5 μm, 5 μm to 15 μm, 5 μm to 10 μm, or 7.5 μm to 15 μM.

In some embodiments, a porous membrane has a thickness of 500 nm to 20 μm, 500 nm to 15 μm, 500 nm to 10 μm, 500 nm to 5 μm, 500 nm to 2.5 μm, 1 μm to 20 μm, 1 μm to 15 μm, 1 μm to 10 μm, 1 μm to 5 μm, 2.5 μm to 20 μm, 2.5 μm to 15 μm, 2.5 μm to 10 μm, 5 μm to 20 μm, 5 μm to 15 μm, or 10 μm to 20 μm.

A porous membrane can be affixed to a flexible mesh using a variety of materials. In some embodiments, a porous membrane is affixed to a flexible mesh by a layer comprising a heat-treated polymer. Heat treated polymers suitable for use with the present invention include polyolefins such as, but not limited to, polyethylene, polypropylene, and the like, and combinations thereof.

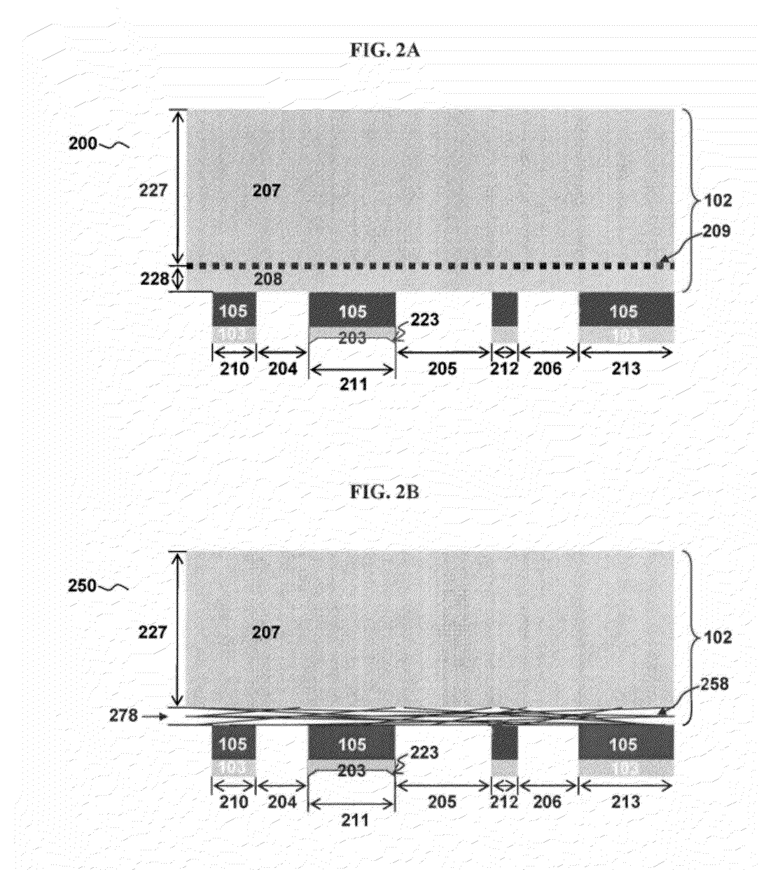

A cross-sectional schematic diagram of a stencil comprising this arrangement is provided in FIG. 2A. Referring to FIG. 2A, the stencil, 200, comprises a porous backing, 102, comprising a flexible mesh, 207, having a thickness, 227. The flexible mesh, 207, is affixed to a porous membrane, 208 (having a thickness, 228), by a layer, 209, comprising a heat-treated polymer (e.g., a polyolefin). The stencil, 200, also includes a stability layer, 105, affixed to the flexible porous backing, 102, via the porous membrane, 208. A contact layer, 103, comprising a photoimaged elastomeric composition is affixed to the stability layer, the contact layer, 103, having lateral dimensions, 210-212, at least one of which is 50 μm or less, the lateral dimensions defining openings, 204-206, in the stencil contact layer of the stencil.

Referring to FIG. 2A, in some embodiments, a contact layer, 203, has a concave or “cup” shape in which the outer edges of the contact layer protrude, 223, from the contact surface. Not being bound by any particular theory, a stencil comprising a contact layer having a protruding edge (i.e., a concave shape) can be particularly suitable for patterning roughened substrates or substrates having significant topographical features. For example, many substrates suitable for in electronics applications, display device components, windows, and the like require a roughened surface. The stencils of the present invention comprise a contact surface that can conformally contact a substrate, and for roughened and uneven substrates the addition of protrusions on the edges of the contact surface can enable conformal contact without loss of feature dimension due to distortion of the contact surface, or incomplete sealing at the edges of the stencil.

In some embodiments, a flexible porous backing comprises a layer of nanowires affixed to a flexible mesh and the stability layer. Nanowires suitable for use with the present invention are not particularly limited by composition, and include metallic, ceramic, polymeric (e.g., polyethylene, polyethylene terephthalate, polyvinylpyrrolidone, and the like), and carbon nanow'res, and the like, and combinations thereof. In some embodiments, the nanowires have a composition and/or are prepared by an electrospinning process described in, for example, U.S. application Ser. Nos. 12/578,219 and 61/227,336, which are incorporated herein by reference in their entireties. Nanowires can also be prepared by a melt-blowing process as described in, for example, U.S. Appl. No. 61/243,917, which is incorporated herein by reference in its entirety. Similar to the porous membrane described above, a layer of nanowires can provide a porous planarization layer such that the stability layer can be affixed to a flexible porous backing comprising a flexible mesh while enabling an etch paste to flow through the flexible porous backing.

A layer of nanowires can be affixed to a flexible mesh using an adhesive (e.g., an epoxy, a polyurethane, and the like), solvent-assisted welding, heat treatment, pressure, and combinations thereof. In some embodiments, a layer of nanowires is electrospun or melt-blown directly onto a flexible mesh and adheres to the flexible mesh by a covalent bond.

In some embodiments, the nanowires have an average diameter of 80 nm to 10 μm, 150 nm to 10 μm, 200 nm to 5 μm, 300 nm to 10 μm, 500 μm to 10 μm, 1 μm to 10 μm, 1.5 μm to 10 μm, 2 μm to 10 μm, 150 nm to 5 μm, 200 nm to 5 μm, or 200 nm to 2 μm. In some embodiments, a layer of nanowires has a thickness of 500 nm to 20 μm, 500 nm to 15 μm, 500 nm to 10 μm, 500 nm to 5 μm, 500 nm to 2.5 μm, 1 μm to 20 μm, 1 μm to 15 μm, 1 μm to 10 μm, 1 μm to 5 μm, 2.5 μm to 20 μm, 2.5 μm to 15 μm, 2.5 μm to 10 μm, 5 μm to 20 μm, 5 μm to 15 μm, or 10 μm to 20 μm.

A cross-sectional schematic diagram of a stencil comprising this arrangement is provided in FIG. 2B. Referring to FIG. 2B, the stencil, 250, comprises a porous backing, 102, comprising a flexible mesh, 207, having a thickness, 227. The flexible mesh, 207, is affixed to a layer of nanowires, 258 (having a thickness, 278). The stencil, 200, also includes a stability layer, 105, affixed to the flexible porous backing, 102, via the porous membrane, 208. A contact layer, 103, comprising a photoimaged elastomeric composition is affixed to the stability layer', the contact layer, 103, having lateral dimensions, 210-212, at least one of which is 50 μm or less, the lateral dimensions defining openings, 204-206, in the stencil contact layer of the stencil. As discussed above, in some embodiments, a contact layer, 203, has a concave or “cup” shape in which the outer edges of the contact layer protrude, 223, from the contact surface.

### Processes for Preparing the Stencils

The present invention is directed to a process for preparing a stencil, the process comprising:

disposing a lift-off layer onto a master that includes at least one light-blocking region that forms an optically transparent pattern;

disposing a photoimageable elastomeric formulation onto the lift-off layer;

illuminating and developing the photoimageable elastomeric formulation to form a contact layer comprising a photoimaged elastomer having at least one opening there through that defines a pattern in the stencil having at least one lateral dimension of 50 μm or less;

disposing a photoimageable formulation onto the contact layer;

contacting a flexible porous backing with at least a portion of the photoimageable formulation;

illuminating the photoimageable formulation to form a stability layer affixed to both the contact layer and the flexible porous backing, wherein the stability layer has a Shore Type D harness of 50 or more, and has lateral dimensions substantially the same as the contact layer; and

removing the stencil from the master by separating or removing the lift-off layer from the stencil.

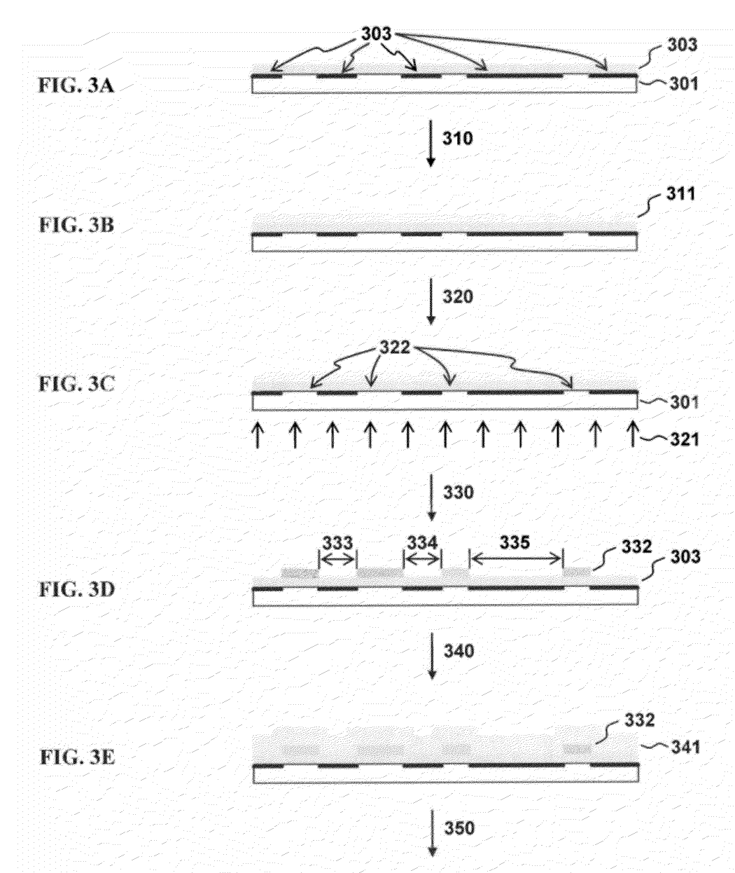

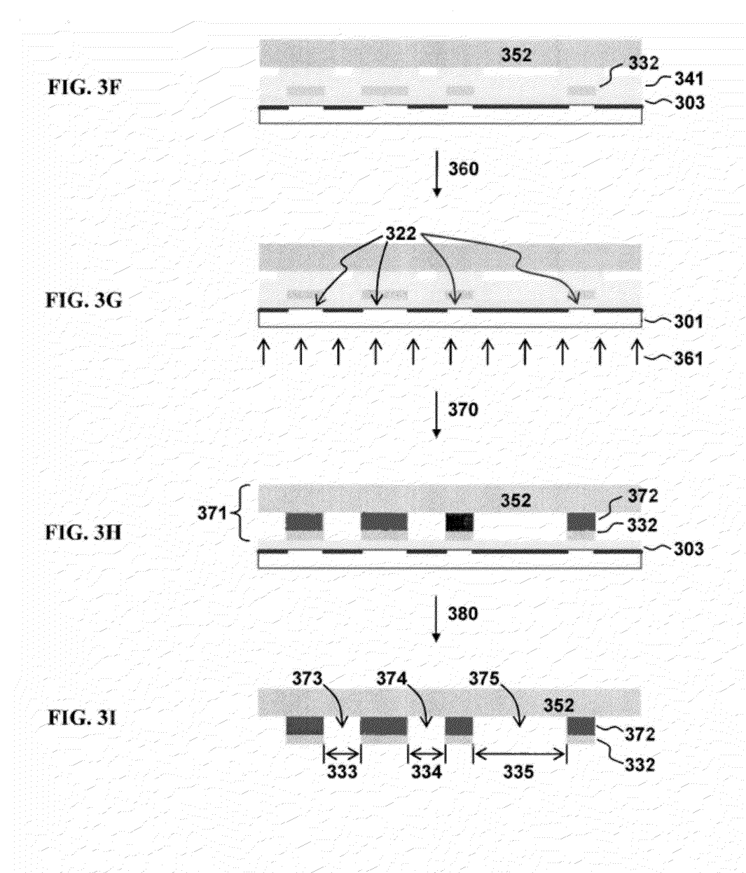

FIGS. 3A-3I provide a cross-sectional schematic diagram illustrating a process of the present invention. Referring to FIG. 3A, a master, 301, comprising at least one light-blocking region, 302, is provided. The master comprises a lift-off layer, 303, deposited thereon.

Materials suitable for use as a lift-off layer include water-soluble polymers that are at least partially transparent to ultraviolet and/or visible light. As used herein, water soluble polymers include those that are very soluble, freely soluble, soluble, and/or sparingly soluble in water at room temperature. In some embodiments, a water-soluble polymer suitable for use with the present invention have a solubility of 100 g per 100 mL or higher, 10 g per 100 mL or higher, 3.3 g per 100 mL or higher, or 1 g per 100 mL or higher in water at room temperature (about 20° to 25° C.). Water soluble polymer suitable for use as a lift-off layer with the present invention include, but are not limited to, a polyvinyl alcohol, a hydroxyalkyl cellulose (e.g., hydroxyethylcellulose and the like), a polysaccharide, a polyvinylpyrrolidone, and the like, and combinations thereof. The polymers form an optically transparent film, which as used herein refers to a minimum transparency (for a thin film having a thickness of 100 μm) of 80% or greater, 85% or greater, 90% or greater, or 95% or greater in the ultraviolet and/or visible range at a wavelength of 230 nm to 600 nm, 250 nm to 550 nm, 250 nm to 500 nm, 250 nm to 450 nm, 250 nm to 400 nm, 275 nm to 500 nm, or 300 nm to 450 nm.

Referring to FIG. 3A, a photoimageable elastomeric formulation is then disposing, 310, onto the lift-off layer, 303. Suitable methods for the disposing include, but are not limited to, spin-coating, chemical vapor depositing, spraying, extruding, doctor blading, and the like. Referring to FIG. 3B, the photoimageable elastomeric formulation, 311, has a composition as described herein above. Specifically, in some embodiments a process comprises disposing a photoimaged elastomeric formulation suitable for providing a photoimaged elastomer having a Shore Type A hardness of 5 to 95.

The photoimageable elastomeric formulation, 311, has a thickness suitable for providing the desired contact layer thickness for the stencil. Typical thicknesses for the film are 1 μm to 10 μm. The photoimageable elastomeric formulation is then illuminated, 320.

Referring to FIG. 3C, light, 321, is directed towards the backside of the master, 301, and passes through openings in the master, 322. Volumes of the photoimageable elastomeric formulation that are exposed to light that passes through patterned master are cross-linked. The light, 321, has a wavelength suitable for absorption by a photoinitiator present in the photoimageable elastomeric formulation. In some embodiments, the light, 321, has a wavelength of 200 nm to 600 nm, 230 nm to 450 nm, about 250 nm, about 275 nm, about 300 nm, or about 350 nm. After the disposing and illuminating, the photoimageable elastomeric formulation is then developed, 330.

The developing, 330, comprises exposing the photoimaged elastomeric formulation to a solvent suitable for dissolving the volumes of the photoimaged formulation that were not illuminated. Conversely, portions of the photoimaged elastomeric formulation that were illuminated are cross-linked and do not dissolve in the developer solution.

In some embodiments, the photoimageable elastomeric formulation does not substantially phase separate prior to the illuminating and developing. Developers suitable for use with the presently claimed invention include solvents described herein as suitable for use as a carrier for the photoimageable elastomeric formulation. In some embodiments, the master is heated during the developing.

In some embodiments, the photoimageable elastomeric formulation does not substantially phase separate prior to illuminating and developing. Phase separation refers to the de-mixing of components from a homogeneous mixture to a heterogeneous composition comprising micro- and/or macro-domains on the order of tens of microns or greater. Phase separation can be detected by analyzing the properties and/or composition of a contact layer after illuminating and developing. For example, phase separation prior to illuminating and developing can result in the formation of a contact layer having, for example, a composition gradient, micro-domains, and the like.

Referring to FIG. 3D, the developing provides a contact layer, 332, comprising a photoimaged elastomer. The contact layer, 332, is on the lift-off layer, 303, and has at least one opening there through that defines a pattern in the contact layer and has at least one lateral dimension, 333-335, of 50 μm or less. In some embodiments, at least one of the lateral dimensions of the openings, 333-335, is 1 μm to 10 μm. A photoimageable formulation is then disposed, 340, onto the contact layer.

Referring to FIG. 3E, the photoimageable formulation, 341, coats the contact layer, 332. For example, by adjusting the viscosity and solvent concentration of the photoimageable formulation, a conformal coating or a planarizing coating can be formed over the contact layer. The photoimageable formulation, 341, has a composition as described herein above. Specifically, the process comprises disposing a photoimaged formulation suitable for providing a stability layer having a Shore Type D hardness of 50 or more. The photoimageable formulation, 341, has a thickness suitable for providing the desired stability layer thickness for the stencil. Typical thicknesses for the film are 5 μm to 50 μm.

In some embodiments, prior to disposing the photoimageable formulation onto a contact layer, a contact layer is treated with an oxygen plasma and an adhesion promoter is disposed onto the oxygen plasma-treated contact layer. Adhesion promoters suitable for use with the present invention include, but are not limited to, trichloro(vinyl)silane, trimethoxy(vinyl)silane, triethoxy(vinyl)silane, 2-acryloxyethoxytrimethoxy silane, 2-acryloxyethoxytriethoxy silane, 2-acryloxyethoxytrichlorosilane, N-3-acryloxy-2-hydroxypropyl-3-aminopropyltriethoxysilane, acryloxymethyltrimethoxysilane, acryloxymethyltriethoxysilane, acryloxymethyltrichlorosilane, acryloxymethyl phenethyltrimethoxysilane, 3-N-allylaminopropyltrimethoxysilane, allyltrimethoxysilane, allyltriethoxysilane, allyltrichlorosilane, and the like, and combinations thereof. Suitable methods for disposing an adhesion promoter include spin-coating, spraying, chemical vapor depositing, brushing, flowing, dip-coating, and the like. An adhesion promoter can be optionally disposed onto a contact layer using an inert gas or liquid carrier.

After disposing the photoimageable formulation onto the contact layer, a flexible porous backing is then contacted, 350, with at least a portion of the photoimageable formulation.

In some embodiments, prior to contacting, 350, a flexible porous backing with at least a portion of the photoimageable formulation, a surface of the flexible porous backing is oxygen plasma-treated. In some embodiments, prior to contacting, 350, a flexible porous backing with at least a portion of a photoimageable formulation, an adhesion promoter is deposited onto the flexible porous backing that has been oxygen plasma-treated. Adhesion promoters and methods of disposing suitable for treating a flexible porous backing include those described herein above.

Referring to FIG. 3F, contacting a flexible porous backing with the photoimageable formulation provides a structure comprising a flexible porous backing, 352, in contact with a photoimageable formulation, 341, which coats, a contact layer, 332, and a lift-off layer, 303. The photoimageable formulation is illuminated, 360.

Referring to FIG. 3G, light, 361, is directed towards the backside of the master, 301, and passes through openings in the master, 322. Volumes of the photoimageable formulation that are exposed to light that passes through patterned master are cross-linked. The light, 361, has a wavelength suitable for absorption by a photoinitiator present in the photoimageable formulation. In some embodiments, the light, 361, has a wavelength of 200 nm to 600 nm, 230 nm to 450 nm, about 250 nm, about 275 nm, about 300 nm, or about 350 nm. The wavelength(s) of light, 361, used for illuminating the photoimageable formulation can be the same or different than the wavelength(s) of light used to illuminate the photoimageable elastomeric formulation. In some embodiments, the illuminating is performed prior to contacting a flexible porous backing with the photoimaged formulation. After the disposing and illuminating, the photoimaged formulation is developed, 370.

As described above, developing, 370, comprises exposing the photoimaged formulation to a solvent suitable for dissolving the volumes of the photoimaged formulation that were not illuminated. Conversely, portions of the photoimaged formulation that were illuminated are cross-linked and do not dissolve in the developer solution. Developers suitable for use with the presently claimed invention include solvents described herein as suitable for use as a carrier for the photoimageable elastomeric formulation. In some embodiments, the master is heated during the developing. As discussed above, phase separation prior to illuminating and developing can result in the formation of a stability layer having, for example, a composition gradient, micro-domains, and the like.

Referring to FIG. 3H, the developing, 370, provides a stencil, 371, comprising a flexible porous backing, 352, affixed to a stability layer, 371, comprising a photoimaged formulation, which is affixed to and has substantially the same lateral dimensions as a contact layer, 332. The contact layer, 332, is formed on a lift-off layer, 303. The stencil, 371, is then removed, 380, from the master.

Removing, 380, comprises separating the stencil from the lift-off layer and/or removing the lift-off layer from the stencil. In some embodiments, the removing comprises dissolving the lift-off layer in a suitable solvent such as an aqueous solvent. Removing can also comprise heating the lift-off layer, sonicating the lift-off layer, applying mechanical force to the lift-off layer, and the like, and combinations thereof.

Referring to FIG. 3G, the removing, 380, provides a stencil, 371, comprising a flexible porous backing, 352, a stability layer, 372, and a contact layer, 332. The contact layer, 332, comprises at least one opening, 373-375, having at least one lateral dimension, 333-335, of 50 μm or less. In some embodiments, the contact layer has a thickness of 1 μm to 10 μm and the stability layer has a thickness of 5 μm to 50 μm.

The flexible porous backing can comprise a layer of nanowires affixed to a flexible mesh and the stability layer. Nanowires suitable for use with the present invention are not particularly limited by composition, and include metallic, ceramic, polymeric (e.g., polyethylene, polyethylene terephthalate, and the like), and carbon nanowires, and the like, and combinations thereof. In some embodiments, the nanowires have a composition and/or are prepared by an electrospinning process described in, for example, U.S. application Ser. Nos. 12/578,219 and 61/227,336, which are incorporated herein by reference in their entireties. Nanowires can also be prepared by a melt-blowing process as described in, for example, U.S. Appl. No. 61/243,917, which is incorporated herein by reference in its entirety.

Not being bound by any particular theory, a layer of nanowires can provide a porous planarization layer such that a stability layer can be affixed thereto. A layer of nanowires can be affixed to a flexible mesh and/or a stability layer using an adhesive (e.g., an epoxy, a polyurethane, and the like), by disposing nanowires having reactive functional groups on their surfaces, solvent-assisted melting or welding, wetting with a non-solvent followed by compression, heat treatment, pressure, and combinations thereof. In some embodiments, a trace solvent or treatment with a solvent such as, but not limited to, isopropyl alcohol (IPA), acetone, dichloromethane (DCM), L′ chloroacetic acid (TCA), and the like, and combinations thereof (e.g., 1:1 TCA and DCM) is used to weld the nanowires to a flexible mesh. In some embodiments, a layer of nanowires is electrospun or melt-blown directly onto a flexible mesh and adheres to the flexible mesh by a covalent bond.

In some embodiments, layer of nanowires is adhered to a flexible mesh and treated with an oxygen plasma and/or an adhesion promoter, as described herein above, before being contacted with at least a portion of a contact layer.

The flexible porous backing can comprise a porous membrane. In some embodiments, a process comprises annealing an assembly that includes a porous membrane having an average pore size of 15 μm or less with a flexible mesh, wherein the annealing melts a plurality of polyolefin-containing particles between the membrane and the mesh, thereby affixing the porous membrane to the flexible mesh. For example, a plurality of polyolefin-containing pellets are placed on a flexible mesh and a porous membrane is disposed thereon. The assembly is then placed between solid members and pressure and heat is applied thereto to melt the polyolefin-containing particles. The heating time and temperature, and the pressure applied to the structure can be varied. The temperature should be maintained within the “softening” region of the plastic microparticles that are placed between the porous membrane and woven mesh. If the temperature is insufficient, then the particles do not melt and the porous membrane and woven mesh do not adhere to each other. However, if the sandwich structure is heated excessively, or for too great a period of time, then pores in the membrane become sealed. Methods for use with the present invention also include those disclosed in U.S. Pat. No. 4,963,261, which is incorporated herein by reference in its entirety.

Polyolefin-containing particles suitable for use with the present invention are not particularly limited by size and shape, and can include a polyolefin such as, but not limited to, polyethylene, polypropylene, and the like, and combinations thereof. In some embodiments, a polyolefin-containing particle has an average lateral dimension of 1 μm to 100 μm, 2 μm to 75 μm, 5 μm to 50 μm, or 5 μm to 40 μm.

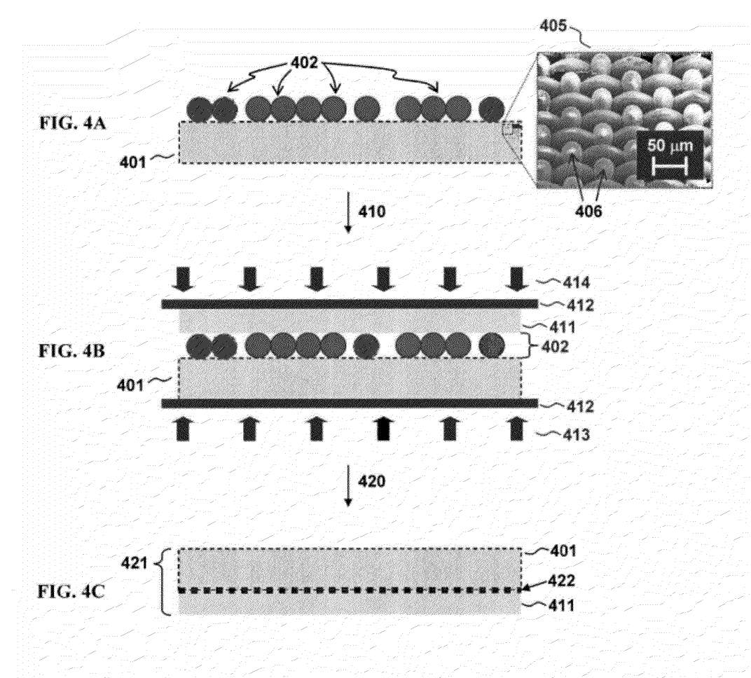

FIGS. 4A-4C provide a schematic cross-sectional diagram of a process suitable for affixing a porous membrane to a flexible mesh. Referring to FIG. 4A, a plurality of particles comprising a polyolefin, 402, are disposed on a flexible mesh, 401. The inset, 405, provides a SEM image of a representative flexible mesh comprising interlocking polyethylene fibers, 406, having an average diameter of about 30 μm. A porous membrane is then contacted, 410, with the polyolefin-containing particles.

Referring to FIG. 4B, the resulting structure comprises a plurality of polyolefin-containing particles, 402, between a porous membrane, 411, and a flexible mesh, 401. Flat plates, 412, are contacted with the backsides of the porous membrane, 411, and flexible mesh, 401, and pressure, 413 and 414, is applied to one or both of the plates. Suitable materials for use as plates include metals, silicon wafers, glasses, ceramics, and the like. Pressures of 100 psi to 15,000 psi, 150 psi to 10,000 psi, or 500 psi to 5,000 psi can be applied to one or both of the plates. Thermal energy can be optionally applied to the structure before, during, and/or after applying pressure (resulting in a temperature of about 50° C. to about 300° C. between the plates). The pressure and/or thermal energy melts the polyolefin-containing particles and affixes the porous membrane, 411, to the flexible mesh, 401. The plates are removed, 420, to provide the flexible porous backing.

Referring to FIG. 4C, a flexible porous backing, 421, is provided, the flexible porous backing comprising a porous membrane, 411, a flexible mesh, 401, and an adhesive layer there between, 422, comprising a polyolefin. In some embodiments, the porous membrane, 411, has an average pore size of 15 μm or less.

The stencils of the present invention are robust and can be utilized numerous times without degradation of the surface of the contact layer. In some embodiments, a stencil of the present invention can pattern at least 50, at least 100, at least 200, or at least 500 patterns prior to exhibiting a deviation of about 5% or more or about 10% or more in a lateral dimension of a pattern prepared therefrom.

### Etch Pastes

The processes of the present invention utilize an etch paste to pattern a substrate. In particular embodiments, an etch paste for use with a stencil of the present invention is a thixotropic mixture having a viscosity of 100 centiPoise (cP) or more. Generally, an etch paste comprises more than one component. As used herein, a “etch paste” can also refer to a gel, a cream, a glue, an adhesive, and any other viscous liquid or semi-solid.

An etch paste comprises an “etchant,” which refers to a component that can react with a substrate to remove a portion of the substrate. In some embodiments, an etchant is present in a concentration of 5% to 80%, 5% to 75%, or 10% to 75% by weight of an etch paste. Suitable etchants include acidic, basic, and fluoride-based etchants, and combinations thereof. Etchants for reacting with various materials are well known in the chemical arts.

Acidic etchants include nitric acid, sulfuric acid, trifluoromethanesulfonic acid, fluorosulfonic acid, trifluoroacetic acid, trichloroacetic acid, phosphoric acid, hydrofluoric acid, hydrochloric acid (HCl), HCl and ferric chloride, hydrobromic acid, carborane acid, tartaric acid, oxalic acid, and combinations thereof.

Basic etchants include sodium hydroxide, potassium hydroxide, ammonium hydroxide, tetraalkylammonium hydroxide, ammonia, ethanolamine, ethylenediamine, and combinations thereof.

Fluoride-based etchants include ammonium fluoride, lithium fluoride, sodium fluoride, potassium fluoride, rubidium fluoride, cesium fluoride, francium fluoride, antimony fluoride, calcium fluoride, ammonium tetrafluoroborate, potassium tetrafluoroborate, and combinations thereof.

Etch pastes suitable for use with the present invention include, but are not limited to, HIPERETCH® and SOLARETCH® (Merck KGaA, Darmstadt, Germany). Additional etch paste compositions containing an etchant that are suitable for use with the present invention are disclosed in U.S. Pat. Nos. 5,688,366 and 6,388,187; and U.S. Pub. Nos. 2003/0160026; 2004/0063326; 2004/0110393; and 2005/0247674, which are herein incorporated by reference in their entirety.

In some embodiments, at the time of application to the backside of a stencil and/or at the time of reacting with a substrate, an etch paste of the present invention has a viscosity of 100 cP to 10,000 cP, 100 cP to 5,000 cP, 100 cP to 1,000 cP, 100 cP to 500 cP, 500 cP to 10,000 cP, 500 cP to 5,000 cP, 500 cP to 1,000 cP, 1,000 cP to 10,000 cP, or 5,000 cP to 10,000 cP.

### Etching Processes

The present invention is directed to a process of etching a substrate, the process comprising:

conformally contacting the contact surface of the stencil of claim 1 with a substrate;

flowing an etch paste comprising an etchant through the porous backing assembly and the at least one opening in the stencil;

reacting the etch paste with the substrate, wherein the reacting removes a portion of the substrate to provide a pattern on the substrate having at least one lateral dimension of 50 μm or less; and

removing the stencil from the substrate.

The present invention is also directed to a process of etching a substrate, the process comprising:

conformally contacting the contact surface of the stencil of claim 1 with a substrate;

flowing an etch paste comprising an etchant through the porous backing assembly and the at least one opening in the stencil to provide a pattern of etch paste on the substrate;

removing the stencil from the substrate; and

reacting the pattern of etch paste with the substrate, wherein the reacting removes a portion of the substrate to provide a pattern on the substrate having at least one lateral dimension of 50 μm or less.

The processes of the present invention produces surface features by reacting an etch paste with an area of a substrate. As used herein, “reacting” refers to initiating a chemical reaction between one or more components of an etch paste and a substrate.

In some embodiments, reacting an etch paste with a substrate comprises reactions that propagate into the plane (i.e., body) of a substrate, as well as reactions in the lateral plane of a surface of the substrate. For example, a reaction between an etchant and a substrate can comprise the etchant penetrating into the surface of the substrate (i.e., penetration orthogonal to the surface), such that the lateral dimensions of the lowest point of the surface feature are approximately equal to the dimensions of the feature at the surface of the substrate.

The present invention minimizes lateral reaction of an etch paste with a substrate, such that the lateral dimensions at the bottom of a surface feature are the same as the lateral dimensions of a feature at the plane of a substrate. Thus, the etching processes minimize “undercut,” which refers to situations when the lateral dimensions of a surface feature are greater than the lateral dimensions of a stencil used to mask a portion of a substrate.

In some embodiments, reacting comprises applying an etch paste to a substrate (i.e., a reaction is initiated upon contact between an etch paste and a surface of a substrate).

In some embodiments, a process of the present invention includes initiating a reaction between an etch paste and a substrate. As used herein, “initiating” refers to a process in which a reaction between a substrate and an etch paste is triggered. Initiating processes suitable for use with the present invention include, but are not limited to, exposing at least one of a substrate, an etch paste, and a stencil to: thermal energy, electromagnetic radiation, acoustic waves, an oxidizing or reducing plasma, an electron beam, a stoichiometric chemical reagent, a catalytic chemical reagent, an oxidizing or reducing reactive gas, an acid or a base (e.g., a decrease or increase in pH), an increase or decrease in pressure, an alternating or direct electrical current, agitation, sonication, friction, and the like, and combinations thereof. In some embodiments, at least one of a substrate, an etch paste and a stencil are individually or collectively exposed to multiple reaction initiators.

Electromagnetic radiation suitable for use as a reaction initiator can include, but is not limited to, microwave light, infrared light, visible light, ultraviolet light, x-rays, radiofrequency, and combinations thereof.

In some embodiments, at least one of a stencil, an etch paste, and/or a substrate is maintained at a temperature of about 25° C. or less, and the temperature is then increased. Thus, the present invention includes a process in which a combination of an etch paste and a substrate capable of undergoing reaction at or near room temperature are utilized in which a reaction is not initiated upon contacting an etch paste with a substrate. Instead, the etch paste, stencil and substrate are maintained at or below a temperature at which reacting does not substantially occur, and a reaction is initiated by heating the etch paste, stencil and/or substrate to a temperature at or above 25° C. for a period of time sufficient to react the etch paste with the substrate.

In some embodiments, a stencil, an etch paste and/or a substrate is maintained at a temperature of −196° C. to 50° C., −196° C. to 25° C., −196° C. to 0° C., −150° C. to 50° C., −150° C. to 25° C., −150° C. to 0° C., −125° C. to 50° C., −125° C. to 25° C., −125° C. to 0° C., −100° C. to 50° C., −100° C. to 25° C., −50° C. to 50° C., −50° C. to 25° C., −25° C. to 50° C. prior to reacting followed by initiating a reaction by actively and/or passively heating the stencil, etch paste and/or substrate. In some embodiments, a process comprises heating a substrate, etch paste and/or stencil to a temperature of 75° C. to 300° C., 75° C. to 250° C., 75° C. to 200° C., 75° C. to 150° C., 100° C. to 300° C., 100° C. to 250° C., 100° C. to 200° C., 100° C. to 150° C., 125° C. to 300° C., 125° C. to 250° C., 125° C. to 200° C., 150° C. to 300° C., 150° C. to 250° C., 175° C. to 300° C., 75° C., 100° C., 125° C., 150° C., 175° C., 200° C., 250° C., or 300° C. to initiate a reaction of an etch paste with a substrate. In some embodiments, a process comprises increasing a temperature of an etch paste, a substrate and/or a stencil by 50° C. to 300° C., 50° C. to 250° C., 50° C. to 200° C., 20° C. to 150° C., 50° C. to 100° C., 75° C. to 300° C., 75° C. to 250° C., 75° C. to 200° C., 75° C. to 150° C., 100° C. to 300° C., 100° C. to 250° C., 100° C. to 200° C., 125° C. to 300° C., 125° C. to 250° C., 125° C. to 200° C., 150° C. to 300° C., 150° C. to 250° C., 200° C. to 300° C., or 250° C. to 300° C.

Thus, in some embodiments the present invention comprises thermally initiating a reaction between an etch paste and a substrate by heating at least one of a stencil, a substrate, and/or an etch paste from a first temperature at which a reaction between an etch paste and a substrate does not substantially occur to a second temperature at which a reaction between an etch paste and a substrate readily occurs. In some embodiments, a thermally initiated process comprises actively cooling a stamp an etch paste, a substrate, or a combination thereof followed by actively or passively heating one or more of the same. In some embodiments, thermal initiation comprises maintaining a stamp, an etch paste, a substrate, or a combination thereof at ambient temperature followed by actively heating to an elevated temperature.

In some embodiments, a stencil is removed from a substrate before reacting an etch paste. In some embodiments, a stencil is removed from a substrate after reacting an etch paste.

Etch pastes can be applied to a back surface of a stencil by pouring, spraying, flowing, brushing, and the like, and combinations thereof. In some embodiments, after an etch paste is applied to a back surface of a stencil an object is moved transversely across the back surface of the stencil to ensure that the etch paste flows into and through the stencil backing. However, the processes of the present invention do not require such mechanical manipulation of the etch paste using, e.g., a squeegee (a flexible member), doctor blade (e.g., a rigid member), meyer bar (also know as a mayer rod, e.g., an optionally coated rigid metal bar), and the like.

Adhesion between an etch paste and a stencil and/or substrate can be promoted by, e.g., gravity, a Van der Waals interaction, a covalent bond, an ionic interaction, a hydrogen bond, a hydrophilic interaction, a hydrophobic interaction, a magnetic interaction, and combinations thereof.

In some embodiments, the backing layer of a stencil is hydrophilic and readily wetted by an etch paste. For example, the backing layer can be treated with an oxygen plasma for a period of time sufficient to render the surface of the backing layer hydrophilic. As used herein, “hydrophilic” refers to an attraction to water, and includes surfaces that form a contact angle of 90° or less with a water droplet. In some embodiments, a backing layer of a stencil is rendered hydrophilic such that a water droplet applied to the backing layer forms a contact angle of 90° or less, 60° or less, 40° or less, 35° or less, 30° or less, 25° or less, 20° or less, 15° or less, or 10° or less. Contact angles can be measured using, e.g., a contact angle goniometer by processes known to persons of ordinary skill in the art.

The processes of the present invention comprise conformally contacting a stencil with a substrate. In preferred embodiments, conformal contact is achieved without applying pressure to the stencil and/or substrate. While applying pressure to a stencil or substrate can ensure an etch paste is not present between a substrate and a stencil surface, applying pressure can result in distortion of a pattern in a surface of a stencil. Therefore, a contact surface of a stencil is conformally contacted with a substrate without applying substantial pressure to either of the substrate or the backside of the stencil. As used herein, “without applying substantial pressure” refers to less than 20 kPa applied to either a backside of the stencil or a substrate. In some embodiments, a stencil merely rests on a substrate without any pressure applied to the backside of a stencil (i.e., the stencil is conformally contacted with a substrate without applied pressure).

Not being bound by any particular theory, the stencils of the present invention enable significantly higher resolution patters to be prepared because of the ability to conformally contact a substrate without applied pressure. This is at least because applying pressure to a stencil can distort the features of the stencil, which significantly reduces the reproducibility of a process and significantly reduces the lifetime of the stencil.

In some embodiments, a contact surface of a stencil, the substrate, or both, are pre-treated with an oxygen plasma prior to conformally contacting the stencil with the substrate.

In some embodiments, a process of the present invention comprises: after flowing the etch paste through a porous backing, increasing the viscosity of the etch paste. For example, an etch paste comprising a cross-linker can be photolytically and/or thermally activated to induce cross-linking within a portion of an etch paste that is on or near a substrate. The resulting cross-linked etch paste has a superior ability to retain its lateral dimensions during a reaction with the substrate, even when the stencil is removed from contact with the substrate prior to the reacting. Thus, the present invention is directed to patterning processes in which an etch paste is reacted with a substrate while a stencil is in contact with the substrate, as well as processes in which a stencil is removed from a substrate prior to the reacting.

In some embodiments, an etch paste of the present invention has a viscosity of 5 cP to 1,000 cP prior to exposure to an external stimulus (e.g., thermal energy, UV light, and the like) and a viscosity of 100 cP to 10,000 cP after the exposure. In some embodiments, an etch paste has a viscosity of 100 cP or more, 250 cP or more, 500 cP or more, 1,000 cP or more, or 5,000 cP or more during the reacting. In some embodiments, an increase in viscosity is attributable to formation of a hydrogel due to partial cross-linking within the etch paste induced by thermal energy and/or exposure to UV light. As discussed above, after removal of a stencil from a substrate reactions between an etch paste and a substrate can be initiated, e.g., thermally.

In some embodiments, a process of the present invention comprises cleaning a patterned substrate. As used herein, “cleaning” refers to a process by which any etch paste, debris, reagents, side-products, and the like, and combinations thereof are removed from a substrate. Cleaning processes suitable for use with the present invention include, but are not limited to, rinsing with a solvent (e.g., water, an alcohol such as ethanol, methanol and the like, a ketone such as acetone and the like); exposing the patterned substrate to a flowing gas such as nitrogen, clean dry air, and the like; placing the patterned substrate in a reactive environment (e.g., a plasma, a chemical bath, and the like); exposing the patterned substrate to electromagnetic radiation, and the like, and combinations thereof. In some embodiments, cleaning comprises rinsing a patterned substrate with water.

### Substrates and Etched Patterns

The present invention is directed to stencils and processes that utilize the stencils for high-throughput, high-resolution etching of substrates. Substrates suitable for use with the present invention are not particularly limited by size, composition or geometry, and include without limitation: planar, curved, symmetric, and asymmetric objects and surfaces, and any combination thereof. Substrates can be homogeneous or heterogeneous in composition, and the processes of the present invention are not limited by surface roughness or surface waviness (i.e., the processes are equally applicable to smooth, rough and wavy surfaces, and substrates exhibiting heterogeneous surface morphology).

As used herein, a “pattern” refers to an area of a substrate that is contiguous with, and can be distinguished from, the areas of the substrate surrounding the pattern. For example, an etched pattern can be distinguished from the areas of the substrate surrounding the etched pattern based upon topography using, e.g., a profilometer, scanning electron microscope, and the like.

Patterns prepared using the stencils of the present invention can be defined by their physical dimensions, which include at least one lateral dimension (i.e., width, length, radius, diameter, circumference, and the like). As used herein, a “lateral dimension” refers to a dimension of a pattern that lies in the plane and/or follows the curvature of a substrate. Two or more lateral dimensions of a pattern define the surface area of a pattern. The processes of the present invention are suitable for providing subtractive patterns in substrates.

In some embodiments, a pattern produced using a stencil of the present invention has at least one lateral dimension of 50 μm or less, 25 μm or less, 10 μm or less, 5 μm or less, or 1 μm or less. In some embodiments, a pattern produced using a stencil of the present invention has at least one lateral dimension of 500 nm to 50 μm, 500 nm to 25 μm, 500 nm to 10 μm, 500 nm to 5 μm, 1 μm to 50 μm, 1 μm to 25 μm, 1 μm to 10 μm, 1 μm to 5 μm, 2.5 μm to 50 m, 2.5 μm to 25 μm, 2.5 μm to 10 μm, 5 μm to 50 μm, 5 μm to 25 μm, 5 μm to 10 μM, 10 μM to 50 μm, 10 μm to 25 μm, 20 μm to 50 μm, 25 μm to 50 μm, 30 μm to 50 μm, or 40 μm to 50 μm.

In some embodiments, a pattern produced using a stencil of the present invention includes a first lateral dimension of 1 μm to 25 μm and a second one lateral dimension of 100 μm or greater, 150 μm or greater, 200 μm or greater, 300 μm or greater, 400 μm or greater, or 500 μm or greater.

In some embodiments, a pattern produced using a stencil of the present invention penetrates into a substrate a distance of 3 Å to 100 μm. In some embodiments, a pattern produced a stencil of the present invention penetrates into a substrate a distance of at least 5 Å, 8 ↑, 1 nm, 2 nm, 5 nm, 10 nm, 15 nm, 20 nm, 30 nm, 50 nm, 100 nm, 500 nm, 1 μm, 2 μm, 5 μm, 10 μm, or 20 μm.

In some embodiments, a pattern produced using a stencil of the present invention has an aspect ratio (i.e., a ratio of depth to width) of 100:1 to 1:100,000, 50:1 to 1:100, 20:1 to 1:80, 15:1 to 1:50, 10:1 to 1:20, 8:1 to 1:15, 5:1 to 1:10, 4:1 to 1:8, 3:1 to 1:5, 2:1 to 1:2, or 1:1.

In some embodiments, a pattern (or a feature thereof) has a surface area of 1 μm² or more, 10 μm² or more, 100 μm² or more, 1,000 μm² or more, 10,000 μm² or more, 100,000 μm² or more, 1 mm² or more, 10 mm² or more, or 100 mm² or more.

In some embodiments, a substrate patterned by a process of the present invention has an area of 400 cm² or greater, 1,000 cm² or greater, 2,000 cm² or greater, 3,000 cm² or greater, 5,000 cm² or greater, 10,000 cm² or greater, 20,000 cm² or greater, or 30,000 cm² or greater. The surface area of a substrate is not particularly limited can be easily scaled by the proper design of equipment suitable for conducting an etching process of the present invention, and can range, without limitation, 1 mm² to 20 m², or 1 cm² to 10 m².

The processes of the present invention are particularly well-suited for etching planar, large-area substrates in a highly-uniform and highly-reproducible manner. As used herein, a “large-area” substrate has an area of about 1,000 cm² or more. For example, the processes of the present invention are particularly well-suited for forming etched patterns on large-area substrates in which the patterns have a substantially uniform density of features. Most contact printing processes are not suitable for use across large areas, but instead can only print large areas in a serial manner, which requires registration of a stamp or stencil and adds complexity to the process. Not being bound by any particular theory, the stencils of the present invention enable contact printing processes to be used on large-area substrates because the flexible backing layer accommodates variations in the surface curvature and/or roughness, and does not require that the stencil be contacted with an entire surface simultaneously. Furthermore, the two-layer system of a contact layer and a stability layer enables the stencil to conformally contact a substrate across the entire surface of the stencil. Thus, the present invention is applicable to etching both large- and small-area substrates.

As used herein, a substrate is “planar” if, after accounting for random variations in the height of a substrate (e.g., surface roughness, waviness, etc.), four points on the surface of the substrate lie in approximately the same plane. Planar substrates include, but are not limited to, windows, displays, embedded circuits, laminar sheets, and the like. Planar substrates include flat variants of the above having holes there through.

As used herein, a substrate is “non-planar” if, after accounting for random variations in the height of a substrate (e.g., surface roughness, waviness, etc.), four or more points on the surface of the substrate do not lie in the same plane. Non-planar substrates include, but are not limited to, gratings, substrates comprising multiple different planar areas (i.e., “multi-planar” substrates), substrates having a tiered geometry, and combinations thereof. Non-planar substrates can include flat and/or curved areas.

As used herein, a “curved” substrate has a radius of curvature that is non-zero over a distance of 1 mm or more across the surface of a substrate.

As used herein, a “rigid” substrate has an elastic modulus of 10 GPa or more. Rigid substrates can undergo temperature-induced distortions due to thermal expansion, or become flexible at temperatures above a glass transition, a melting point, and the like.

As used herein, a “flexible” substrate has a plane, curvature, and/or geometry that can be distorted flexed, and/or undergo elastic or plastic deformation, bending, compression, twisting, and the like in response to applied external force, stress, strain and/or torsion. Typically, a flexible substrate can be moved between flat and curved geometries. Flexible substrates suitable for use with the present invention include, but are not limited to, polymers (e.g., plastics), woven fibers, thin films, metal foils, composites thereof, laminates thereof, and combinations thereof. In some embodiments, a flexible substrate has an elastic modulus less than 10 GPa. In some embodiments, a flexible substrate can be patterned using the processes of the present invention in a reel-to-reel manner.

Substrates for use with the present invention are not particularly limited by composition, and include without limitation, materials selected from: metals, crystalline materials (e.g., monocrystalline, polycrystalline, and partially crystalline materials), amorphous materials, conductors, semiconductors, insulators, optics, painted substrates, fibers, glasses, ceramics, zeolites, plastics, thermosetting and thermoplastic materials (e.g., optionally doped: polyacrylates, polycarbonates, polyurethanes, polystyrenes, cellulosic polymers, polyolefins, polyamides, polyimides, resins, polyesters, polyphenylenes, and the like), films, thin films, foils, plastics, polymers, wood, fibers, minerals, biomaterials, living tissue, bone, alloys thereof, composites thereof, laminates thereof, porous variants thereof, doped variants thereof, and combinations thereof.

In some embodiments, the substrates are transparent to visible, UV, and/or infrared light). In some embodiments, a substrate for use with the present invention has a percent transmission in a wavelength range of about 450 nm to about 900 nm, and/or about 8 μm to about 13 of 90% or more.

In some embodiments, at least a portion of a substrate is conductive or semiconductive. Electrically conductive and semiconductive materials include, but are not limited to, metals, alloys, thin films, crystalline materials, amorphous materials, polymers, laminates, foils, plastics, and combinations thereof. In some embodiments, a substrate for use with the present invention comprises a semiconductor such as, but not limited to, silicon (e.g., crystalline, polycrystalline, amorphous, p-doped, or n-doped silicon, and the like), a metal oxide (e.g., silicon, hafnium, zirconium, and the like), silicon germanium, germanium, gallium arsenide, gallium arsenide phosphide, indium tin oxide, and combinations thereof.

In some embodiments, a substrate for use with the present invention comprises a glass such as, but not limited to, undoped silica glass (SiO₂), fluorinated silica glass, borosilicate glass, borophosphorosilicate glass, organosilicate glass, a porous variant thereof, and combinations thereof.

In some embodiments, a substrate for use with the present invention comprises a metal oxide such as, but not limited to, tin oxide, tin-doped indium oxide or indium-doped tin oxide (“ITO”), zinc oxide, aluminum-doped zinc oxide (“AZO”), gallium-dope zinc oxide (“GZO”), indium-doped cadmium oxide, copper-indium-gallium-selenide, copper-indium-gallium-sulfide, copper-indium-gallium-selenide doped with sulfide, cadmium telluride, and the like, and combinations thereof.

In some embodiments, a substrate for use with the present invention comprises a conductive metal oxide and/or a semiconductive metal oxide layer over an insulating underlayer. In some embodiments, a metal oxide has an optical transparency of 60% or more, 70% or more, 80% or more, 90% or more, or 95% or more at a wavelength of about 380 nm to about 1.8 μm. Thus, in some embodiments a substrate to be patterned by a process of the present invention comprises a transparent conductive oxide and an insulator such as, but not limited to, ITO on glass, AZO on glass, GZO on glass, zinc oxide on glass, and the like, and combinations thereof.

In some embodiments, a substrate comprises a ceramic such as, but not limited to, zinc sulfide (ZnSₓ), boron phosphide (BPₛ), gallium phosphide (GaPₓ), silicon carbide (SiCₓ), hydrogenated silicon carbide (H:SiCₓ), silicon nitride (SiNₓ), silicon carbonitride (SiCₓN_{y}), silicon oxynitride (SiOₓN_{y}), silicon oxycarbide (SiOₓC_{y}), silicon carbon-oxynitride (SiCₓO_{y}N_{z}), hydrogenated variants thereof, doped variants (e.g., n-doped and p-doped variants) thereof, and combinations thereof (where x, y, and z can vary independently from about 0.1 to about 5, about 0.1 to about 3, about 0.2 to about 2, or about 0.5 to about 1).

As discussed herein above, the stencils of the present invention are particularly suitable for patterning roughened substrates and substrates having topographical features thereon. In some embodiments, a substrate patterned by the present invention has a surface roughness of (Ra, based on an arithmetic average of absolute values) 50 nm to 1 mm, 500 nm to 1 mm, 1 μm to 1 mm, 5μm to 1 mm, 10 μm to 1 mm, 50 μm to 1 mm, 100 μm to 1 mm, or 500 μm to 1 mm. In particular, the present invention is suitable for patterning substrates roughened by a chemical etchant, sandblasting, mechanical abrasion, and the like.

In some embodiments, the present invention is directed to a process for etching ITO on glass comprising a process described herein that employs an etch paste that includes aqueous phosphoric acid, aqueous nitric acid, or a combination thereof and has a viscosity of 100 cP or more. In some embodiments, the etch paste comprises poly-N-vinylpyrrolidone.

The patterned substrates prepared by a process of the present invention can be structurally and compositionally characterized using analytical processes known to those of ordinary skill in the art of thin film and/or surface characterization.

### Products

The processes and products prepared from the processes of the present invention are suitable for application in electrical systems, optical systems, consumer electronics, industrial electronics, automobiles, military applications, wireless systems, space applications, and any other applications in which a patterned substrate is required or desirable.

The present invention is also directed to articles, objects and devices comprising a patterned substrate prepared by a process of the present invention. Exemplary articles, objects and devices comprising the patterned substrates of the present invention include, but are not limited to, windows; mirrors; optical elements (e.g., optical elements for use in eyeglasses, cameras, binoculars, telescopes, and the like); lenses (e.g., fresnel lenses, etc.); watch crystals; optical fibers, output couplers, input couplers, microscope slides, holograms; cathode ray tube devices (e.g., computer and television screens); optical filters; data storage devices (e.g., compact discs, DVD discs, CD-ROM discs, and the like); flat panel electronic displays (e.g., LCDs, plasma displays, and the like); touch-screen displays (such as those of computer touch screens and personal data assistants); solar cells; flexible electronic displays (e.g., electronic paper and books); cellular phones; global positioning systems; calculators; graphic articles (e.g., signage); motor vehicles (e.g., wind screens, windows, displays, and the like); artwork (e.g., sculptures, paintings, lithographs, and the like); membrane switches; jewelry; and combinations thereof.

In some embodiments, a patterned substrate prepared by a process of the present invention is used as a layer in a display or optical device that contains additional optional coatings applied thereto (e.g., filters, protective layers and/or anti-reflective coatings, and the like).

Having generally described the invention, a further understanding can be obtained by reference to the examples provided herein. These examples are given for purposes of illustration only and are not intended to be limiting.

### EXAMPLES

### Example 1

In order to prepare a first flexible porous backing for use with a stencil of the present invention thermopolymer microparticles (comprised of, e.g., polypropylene), were applied to a woven mesh or a porous (e.g., polyester) membrane. The particles were either disposed directly onto the woven mesh or porous membrane or disposed onto the woven mesh or porous membrane from a suspension in a solvent having a low vapor point (e.g., ethanol), in which case the solvent was evaporated after disposing the particle-containing suspension onto the surface. The particle application process was carefully controlled to ensure uniform coverage of the woven mesh or porous membrane. A uniform particle density across the surface of the woven mesh or porous membrane is necessary in order to prevent pore sealing, and local buckling of the mesh-membrane hybrid due to insufficient support. After disposing the particles onto the woven mesh or porous membrane, the work pieces were aligned with each other to form a mesh-membrane “sandwich” structure, which was first placed on a flat plate on a hotplate, then covered with a second plate. Pressure (>100 psi) was then applied to the upper plate and the hot plate was set at a temperature of about 150° C. After pressing and heating for about 10 seconds to 5 minutes, a flexible backing for a stencil of the present invention was formed.

As described herein, the heating time and temperature, and the pressure applied to the structure can be varied. The temperature should be maintained within the “softening” region of the plastic microparticles that are placed between the porous membrane and woven mesh. If the temperature is insufficient, then the particles do not melt and the porous membrane and woven mesh do not adhere to each other. However, if the sandwich structure is heated excessively, or for too great a period of time, then pores in the membrane become sealed.

### Example 2

A second flexible porous backing for use with a stencil of the present invention was prepared by disposing flexible nanowires onto a woven mesh. The flexible nanowires (e.g., polyethylene terephthalate (PET); however, a urethane or any other thermoplastic polymer can be used) were electrospun directly onto a woven mesh to create a nanowire-woven fiber composite porous backing. PET (1% to 10% w/v) was dissolved in trifluoroacetic acid and dichloromethane (1:1 v/v) at room temperature and loaded into a 10 mL glass syringe. The loaded glass syringe was placed in a syringe pump (KD Scientific, Holliston, Mass.) and a 20-gauge stainless steel needle was attached thereto. The needle was electrically connected to a variable high-voltage power supply. Flexible mesh was attached to a rotating drum having a 4-inch diameter that was grounded relative to the power supply and set a distance of 10 cm to 20 cm from the needle tip. The rotating drum was supported on a table that allowed for translation in the direction perpendicular to the electrospinning needle, which was located at the same height and to the left of the drum. Nanowires were disposed onto the flexible mesh by flowing the PET solution (i.e., 0.05 L/hr to 0.5 L/hr), at a voltage of 12 keV to 20 keV. The drum was rotated and moved laterally (i.e., “back-and-forth”) at a fixed distance from the needle tip until a uniform nanowire coating was achieved. The nanowire density was sufficient to span the openings in the woven mesh.

### Example 3

A third flexible porous backing for use with a stencil of the present invention was prepared by melt-blowing a thermoplastic polymeric nanowires (comprising, e.g., polyethylene terephthalate (PET), or a urethane, or another thermoplastic polymer), onto a woven mesh to create a nanowire-woven fiber composite porous backing.

PET pellets were loaded into the hopper of a melt-blowing line and melted in a 3-zone single-screw extruder to a final temperature of 265° C. A heated metering pump fed the composition in a 120-hole die having a hole size of 0.015 in, an air gap of 0.06 in, a setback of 0.06 in, and a die angle of 30°. The air flow at the die was >300 L/min and the air temperature at the die was 260-350° C. The extruded polymeric nanowires having a diameter of several hundred nanometers to several micrometers were collected on a woven mesh loaded on a rotating (5-100 feet/min) belt located 10 to 50 cm from the die head. The nanowire density was sufficient to span the openings in the woven mesh.

### Example 4

A stencil of the present invention was prepared by spin-coating (1,000 rpm, at 25° C.) an aqueous solution (e.g., 1% w/v in deionized water) comprising a polymer (e.g., poly(vinylalcohol) (PVA) having an average molecular weight of 9,000-10,000, Sigma-Aldrich, St. Louis, Ill.), 1% w/v in deionized water), to provide a lift-off layer having a thickness of about 0.2 μm to about 1 μm on a patterned master (0.5″ to 5″ diameter, 100 μm to 200 μm-thick glass patterned with thin film of Al or Cr in a pattern corresponding to the desired stencil pattern). An adhesion promoter (i.e., trichloro(vinyl)silane) was vapor deposited onto the lift-off layer by placing the patterned master in a vacuum chamber into which trichloro(vinyl)silane was also introduced. The vapor-phase deposition proceeded at low vacuum (>500 mT) at 25° C. for 5 to 10 minutes. A photoimageable elastomeric formulation having the composition listed in the following table was then spin-coated (2,000 rpm, at 25° C.) onto the lift-off layer. After drying at room temperature (25° C.) for 10 to 20 minutes, the photoimageable elastomeric formulation was exposed to UV light (λ=300 nm-450 nm, peak λ=365 nm; 18-20 mW/cm2; for 8-13 secs) through the back surface of the patterned master. The photoimaged elastomeric formulation was then developed by stirring in toluene for 5 to 10 minutes at 25° C. to provide a patterned contact layer.

TABLE
Composition of the photoimageable elastomeric formulation.

| Component | Concentration |
|---|---|
| Styrene-butadiene-styrene block copolymer | 240 g/L |
| (KRATON ® H5125, Kraton Polymers, Houston, TX) | |
| SARTOMER ® diacrylate (SR9003) | 50 g/L |
| 2-Methyl-1[4-(methylthio)phenyl]-2-morpholinopropan- | 10 g/L |
| 1-one (CIBA ® IRGACURE ® 907, Ciba Specialty | |
| Chemicals, Tarytown, NY) | |
| 4-methylbenzophenone & 2,4,6-trimethylbenzophenone | 3 mL/L |
| (ESACURE ® TZT, Lamberti S.p.A.) | |
| Lauryl-N,N-diethylaminophenylsulfonylpentanienoate, | 500 mg/L |
| free radical scavenger (FUJI ® DPL, Ciba Specialty | |
| Chemicals, Tarytown, NY) | |
| Solvent (3:1 v/v mixture of xylene and cymene) | |

The contact layer was functionalized with an adhesion promoter. After exposure to an air plasma (about 5 minutes) or an oxygen plasma (100 W, 50 mTorr for about 1 minute), an adhesion promoter (e.g., trichloro(vinyl)silane) was vapor deposited onto the plasma-treated surface as described above.

A photoimageable formulation having the composition listed in the following table was then spin-coated followed (2,000 rpm, at 25° C.) onto the contact layer.

TABLE
Composition of the photoimageable formulation.

| Component | Concentration |
|---|---|
| 1,3,5-Triallyl-1,3,5-triazine-2,4,6(1H,3H,5H)-trione | 50% (w/w) |
| (Sigma-Aldrich, St. Louis, IL) | |
| Pentaerythritol tetrakis(2-mercaptoacetate) | 45% (w/w) |
| (Cross-linker, Sigma-Aldrich, St. Louis, IL) | |
| 2-Methyl-1[4-(methylthio)phenyl]-2-morpholinopropan- | 1% (w/w) |
| 1-one (CIBA ® IRGACURE ® 907, Ciba | |
| Specialty Chemicals, Tarytown, NY) | |
| tert-Butylhydroquinone (inhibitor, Sigma-Aldrich, | 3.5% (w/w) |
| St. Louis, IL) | |
| Free radical scavenger (ESACURE ® DPL, Ciba | 0.5% (w/w) |
| Specialty Chemicals, Tarytown, NY) | |

The flexible porous backing prepared in Example 1 was contacted with the wet photoimageable formulation and light pressure (<1 psi) was applied. The photoimageable formulation was then exposed to UV light (λ=300 nm to 450 nm, peak λ=365 nm; 18-20 mW/cm²; for 2 to 10 seconds) through the back surface of the patterned master. The photoimaged elastomeric formulation was then developed by washing with toluene with agitation for 2 to 10 minutes at 25° C. to provide a patterned contact layer.

The stencil was removed from the master by agitating with warm deionized water (30° to 70° C.) for 0.5 to 12 hours.

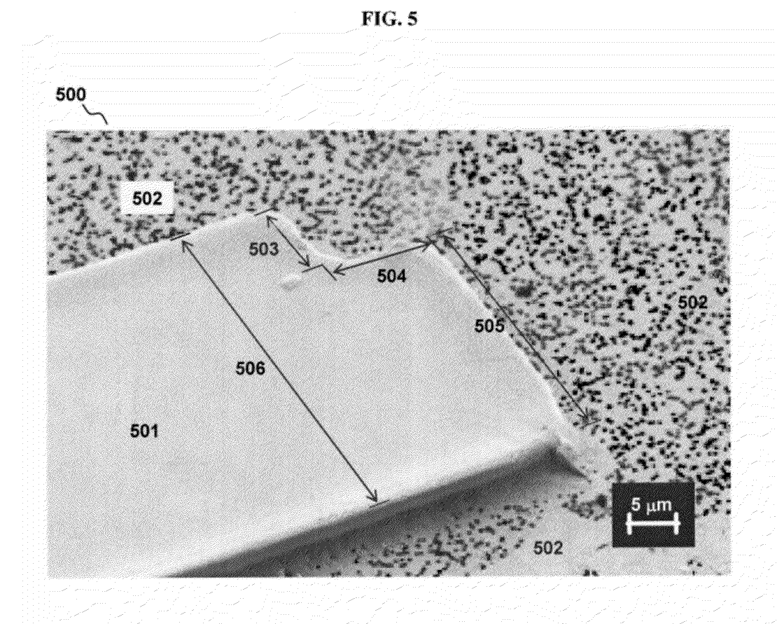

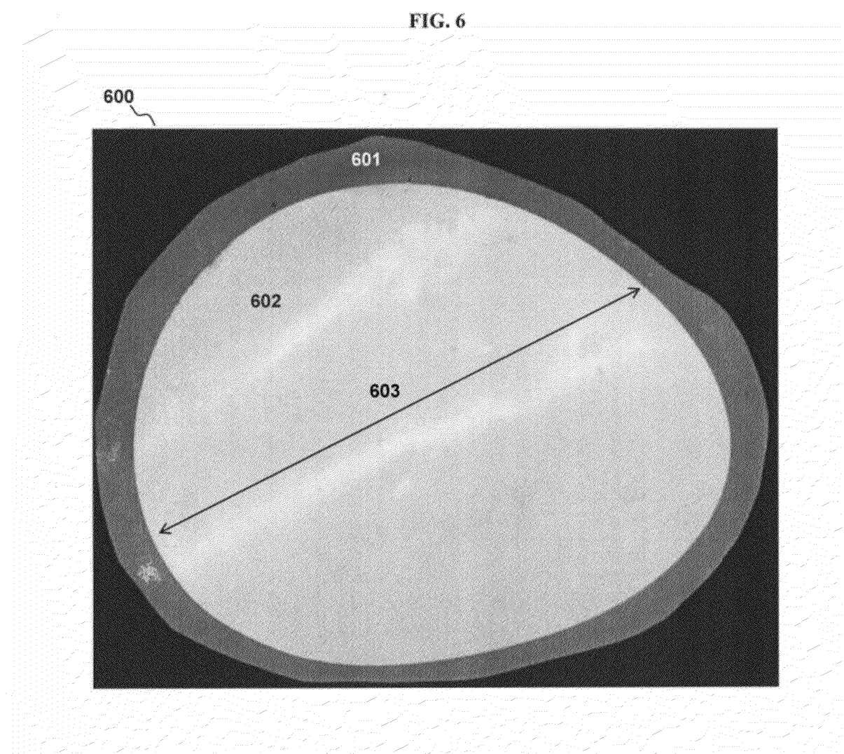

FIG. 5 provides a SEM image of the contact layer and stability layer on the flexible porous backing. Referring to FIG. 5, the image, 500, shows the outer surface, 501, of a contact layer supported on a porous membrane, 502, by a stability layer (not indicated). The stencil feature has lateral dimensions 503-506, at least one of which is 50 μm or less.

FIG. 6 provides an optical image of a stencil of the present invention. Referring to FIG. 6, the image, 600, shows a flexible porous backing comprising a flexible mesh, 601, having a porous membrane thereon, 602, the flexible porous backing supporting a plurality of raised features. The working surface of the stencil has a lateral dimension, 603, of about 50 mm.

### Example 5

A second stencil was prepared by the process described in Example 4 using the flexible porous backing described in Example 2.

### Comparative Example A

A stencil was prepared by the process of Example 3 except that a flexible mesh having a mesh diameter of about 30 μm was contacted directly with the photoimageable formulation (without the a porous membrane affixed to the flexible mesh).

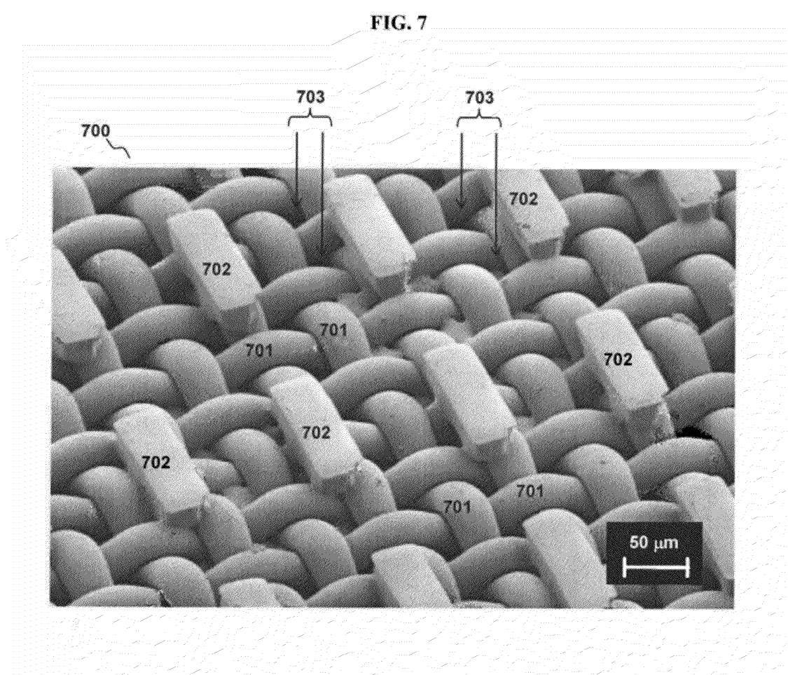

A SEM image of the resulting stencil is provided in FIG. 7. Referring to FIG. 7, the image, 700, shows a flexible mesh, 701, having a contact surface, 702, applied directly thereto. Also visible are openings, 703, in the flexible mesh.

### CONCLUSION

These examples illustrate possible embodiments of the present invention. While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

It is to be appreciated that the Detailed Description section, and not the Summary and Abstract sections, is intended to be used to interpret the claims. The Summary and Abstract sections can set forth one or more, but not all exemplary embodiments of the present invention as contemplated by the inventor(s), and thus, are not intended to limit the present invention and the appended claims in any way.

All documents cited herein, including journal articles or abstracts, published or corresponding U.S. or foreign patent applications, issued or foreign patents, or any other documents, are each entirely incorporated by reference herein, including all data, tables, figures, and text presented in the cited documents.

1. A stencil comprising:
a contact surface that includes
a photoimaged elastomeric composition having at least one opening there through that defines a pattern in the stencil having at least one lateral dimension of 50 μm or less, wherein the photoimaged elastomeric composition is suitable for conformally contacting a substrate; and
a stability layer affixed to a backside of the photoimaged elastomeric composition, wherein the stability layer has substantially the same lateral dimensions as the photoimaged elastomeric composition, and wherein the stability layer has a Shore Type D hardness of 50 or more; and
a flexible porous backing affixed to the stability layer, wherein the flexible porous backing has a permeability suitable for flowing an etch paste there through.

2.-4. (canceled)

5. The stencil of claim 1, wherein the photoimaged elastomeric composition comprises an elastomer, a cross-linker, a photoinitiator, a free radical scavenger, and an optional oxygen scavenger.

6. The stencil of claim 5, wherein the elastomer is selected from the group consisting of: a styrene-butadiene-styrene block copolymer, a styrene-isoprene-styrene block copolymer, a copolymer of acrylonitrile and butadiene, a neoprene rubber, and combinations thereof.

7. (canceled)

8. The stencil of claim 5, wherein
the cross-linker is present in a concentration of 0.5% to 65% by weight,
the photoinitiator is present in a concentration of 0.01% to 10% by weight,
the free radical scavenger is present in a concentration of 0.01% to 15% by weight, and
the optional oxygen scavenger is present in a concentration of 0.01% to 10% by weight.

9. (canceled)

10. The stencil of claim 1, wherein the stability layer comprises a photoimaged polymer composition that includes an aliphatic urethane diacrylate polymer, an optional cross-linker, a photoinitiator, a free radical scavenger, and an optional oxygen scavenger.

11. The stencil of claim 10, wherein
the aliphatic urethane diacrylate polymer is present in a concentration of 5% to 99% by weight,
the optional cross-linker is present in a concentration of 0.5% to 90% by weight,
the photoinitiator is present in a concentration of 0.01% to 10% by weight,
the free radical scavenger is present in a concentration of 0.01% to 15% by weight, and
the optional oxygen scavenger is present in a concentration of 0.01% to 10% by weight.

12. The stencil of claim 1, wherein the flexible porous backing comprises a flexible mesh having openings with a lateral dimension of 1 μm to 100 μm.

13. The stencil of claim 1, wherein the flexible porous backing comprises:
a porous membrane affixed to the stability layer, wherein the porous membrane has an average pore size of 15 μm or less; and
a flexible mesh affixed to the porous membrane, wherein the flexible mesh has openings with a lateral dimension greater than the pore size of the porous membrane.

14-15. (canceled)

16. The stencil of claim 13, wherein a thin layer comprising a heat-treated polyolefin is present between the porous membrane and the flexible mesh.

17. (canceled)

18. The stencil of claim 1, wherein the flexible porous backing comprises:
a layer of nanowires affixed to the stability layer, wherein the nanowires have an average diameter of 80 nm to 10 μm; and
a flexible mesh affixed to the layer of nanowires.

19.-21. (canceled)

22. A process for preparing a stencil, the process comprising:
disposing a lift-off layer onto a master that includes at least one light-blocking region that forms an optically transparent pattern;
disposing a photoimageable elastomeric formulation onto the lift-off layer;
illuminating and developing the photoimageable elastomeric formulation to form a contact layer comprising a photoimaged elastomer having at least one opening there through that defines a pattern in the stencil having at least one lateral dimension of 50 μm or less;
disposing a photoimageable formulation onto the contact layer;
contacting a flexible porous backing with at least a portion of the photoimageable formulation;
illuminating the photoimageable formulation to form a stability layer affixed to both the contact layer and the flexible porous backing, wherein the stability layer has a Shore Type D harness of 50 or more, and has lateral dimensions substantially the same as the contact layer; and
removing the stencil from the master by separating or removing the lift-off layer from the stencil.

23. The process of claim 22, wherein the photoimageable elastomeric formulation does not substantially phase separate prior to the illuminating and developing, and the photoimageable formulation does not substantially phase separate prior to the illuminating.

24. The process of claim 22, comprising, prior to the disposing the photoimageable formulation onto the contact layer, oxygen plasma-treating the contact layer and depositing an adhesion promoter onto the oxygen plasma-treated contact layer.

25. The process of claim 22, comprising, prior to the contacting the flexible porous backing with at least a portion of the photoimageable formulation, oxygen plasma-treating a surface of the flexible porous backing and depositing an adhesion promoter onto the oxygen plasma-treated flexible porous backing.

26.-27. (canceled)

28. The process of claim 22, comprising:
annealing an assembly that includes:
a porous membrane having an average pore size of 15 μm or less;
a flexible mesh; and
a plurality of polyolefin-containing particles there between,
for a time, and at a temperature and pressure sufficient to affix the porous membrane to the flexible mesh to provide a flexible porous backing for the stencil.

29. (canceled)

30. The process of claim 22, comprising:
providing an assembly that includes a layer of nanowires affixed to a flexible mesh, wherein the nanowires have an average diameter of 80 nm to 10 μm.

31. (canceled)

32. The process of claim 22, wherein the lift-off layer comprises a water soluble polymer.

33.-35. (canceled)

36. A stencil comprising:
a first layer comprising a flexible mesh; and
a second layer affixed to the first layer, the second layer comprising a plurality of nanowires, the nanowires having a diameter of 80 nm to 10 μm,
wherein a pattern having at least one lateral dimension of 500 μm or less is present in or on the second layer, and
wherein the flexible porous backing has a permeability suitable for flowing an etch paste there through and the pattern is impermeable to the etch paste.

37. The stencil of claim 36, wherein the nanowires comprise a polymer selected from the group consisting of: polyethylene, polypropylene, polyethylene terephthalate, polyvinylpyrrolidone, and combinations thereof.

38.-40. (canceled)

41. The stencil of claim 36, wherein the pattern comprises an opaque material selected from the group consisting of: a polymer, an elastomer, a metal, and combinations thereof.
